(19) United States
(12) Patent Application Publication
(10) Pub. No.: US 2019/0332009 A1
(43) Pub. Date: Oct. 31, 2019

(54) COLORING COMPOSITION, CURED FILM, STRUCTURE, COLOR FILTER, SOLID-STATE IMAGING ELEMENT, AND IMAGE DISPLAY DEVICE

(71) Applicant: FUJIFILM Corporation, Tokyo (JP)

(72) Inventors: Hirotaka TAKISHITA, Haibara-gun (JP); Kazuya OOTA, Haibara-gun (JP)

(73) Assignee: FUJIFILM Corporation, Tokyo (JP)

(21) Appl. No.: 16/507,373

(22) Filed: Jul. 10, 2019

Related U.S. Application Data
(63) Continuation of application No. PCT/JP2018/001206, filed on Jan. 17, 2018.

(30) Foreign Application Priority Data
Feb. 13, 2017 (JP) 2017-023921

(51) Int. Cl. G03F 7/00; G03F 7/033; G02B 1/04

(52) U.S. Cl. CPC G03F 7/0007; G02F 1/133514; G02B 1/04; G03F 7/033

(57) ABSTRACT

A coloring composition includes a pigment, a resin, and a curable compound, in which the pigment includes a red pigment, a yellow pigment, and an orange pigment, and a mass ratio of the yellow pigment to the red pigment and a mass ratio of the orange pigment to the red pigment in the coloring composition are yellow pigment/red pigment=1.0 to 2.0/1.0 and orange pigment/red pigment=0.9 to 2.0/1.0, respectively.

### CROSS-REFERENCE TO RELATED APPLICATIONS

This application is a Continuation of PCT International Application No. PCT/JP2018/001206 filed on Jan. 17, 2018, which claims priority under 35 U.S.C § 119(a) to Japanese Patent Application No. 2017-023921 filed on Feb. 13, 2017. Each of the above application(s) is hereby expressly incorporated by reference, in its entirety, into the present application.

### BACKGROUND OF THE INVENTION

### 1. Field of the Invention

The present invention relates to a coloring composition. The present invention further relates to a cured film, a structure, a color filter, a solid-state imaging element, and an image display device, each of which uses a coloring composition.

### 2. Description of the Related Art

In recent years, as a digital camera, a mobile phone with a camera, and the like have been further spreading, there has been a greatly increasing demand for a solid-state imaging element such as a charge coupled device (CCD) image sensor. A color filter has been used as a key device in a display or optical element.

In the color filter, color combination using two or more kinds of pigments has been performed in order to obtain desired color characteristics. For example, JP2009-216952A describes a red coloring composition for a color filter, including an orange pigment, a red pigment, a yellow pigment, and a pigment carrier, in which a film thickness of a coating film is 0.5 to 2.5 μm, a transmittance in a wavelength range of 450 to 500 nm is 5% or less, a ratio (T550/T500) of the transmittance (T500) at a wavelength of 500 nm to the transmittance (T550) at a wavelength of 550 nm is 3 or more, and the transmittance at a wavelength of 600 nm is 70% or more in a case where the coating film having a transmittance of 50% in a wavelength range of 575 to 585 nm using the red coloring composition is formed.

### SUMMARY OF THE INVENTION

In recent years, in a cured film for use in a color filter or the like, there is a demand for further improvement of light fastness. In addition, according to the studies conducted by the present inventors, it was found that a cured film obtained from the coloring composition described in JP2009-216952A does not reach a recently required level of light fastness, and thus, the light fastness is insufficient.

Therefore, an object of the present invention is to provide a coloring composition capable of forming a cured film having excellent light fastness. Another object of the present invention is to provide a cured film, a structure, a color filter, a solid-state imaging element, and an image display device.

According to the studies conducted by the present inventors, it was found that it is possible to form a cured film having excellent light fastness with a coloring composition including a pigment, a resin, and a curable compound, in which a red pigment, an orange pigment, and a yellow pigment are used at a predetermined ratio as the pigment, thereby leading to completion of the present invention. The present invention provides the following aspects.

<1> A coloring composition comprising:

a pigment;

a resin; and

a curable compound,

in which the pigment includes a red pigment, a yellow pigment, and an orange pigment, and

a mass ratio of the yellow pigment to the red pigment and a mass ratio of the orange pigment to the red pigment in the coloring composition are yellow pigment/red pigment=1.0 to 2.0/1.0 and orange pigment/red pigment=0.9 to 2.0/1.0, respectively.

<2> The coloring composition as described in <1>,

in which the red pigment is at least one selected from a diketopyrrolopyrrole compound, a quinacridone compound, an anthraquinone compound, a perylene compound, or an azo compound.

<3> The coloring composition as described in <1> or <2>,

in which the red pigment is Color Index Pigment Red 254.

<4> The coloring composition as described in any one of <1> to <3>,

in which the orange pigment is at least one selected from a diketopyrrolopyrrole compound, an azo compound, a pyranthrone compound, a pyrazolone compound, or a phenanthroline compound.

<5> The coloring composition as described in any one of <1> to <4>,

in which the orange pigment is Color Index Pigment Orange 71.

<6> The coloring composition as described in any one of <1> to <5>,

in which the yellow pigment is at least one selected from an isoindoline compound, an azo compound, or a quinophthalone compound.

<7> The coloring composition as described in any one of <1> to <6>,

in which the yellow pigment is Color Index Pigment Yellow 139.

<8> The coloring composition as described in <1>,

in which the red pigment is Color Index Pigment Red 254, the orange pigment is Color Index Pigment Orange 71, and the yellow pigment is Color Index Pigment Yellow 139.

<9> The coloring composition as described in any one of <1> to <8>,

in which the curable compound contains a compound including 3 or more ethylenically unsaturated bond groups.

<10> The coloring composition as described in <9>,

in which the compound including 3 or more ethylenically unsaturated bond groups further has an alkyleneoxy group.

<11> The coloring composition as described in any one of <1> to <10>,

in which the curable compound includes a compound having ethylenically unsaturated bond groups, and a content of a compound including 3 or more ethylenically unsaturated bond groups in the compound having ethylenically unsaturated bond groups is 60% by mass or more.

<12> The coloring composition as described in any one of <1> to <11>, further comprising an ultraviolet absorber.

<13> A cured film obtained from the coloring composition as described in any one of <1> to <12>.

<14> A structure comprising an oxygen-shielding film formed on the cured film as described in <13>.

<15> A color filter comprising the cured film as described in <13>.

<16> A solid-state imaging element comprising the color filter as described in <15>.

<17> An image display device comprising the color filter as described in <15>.

According to the present invention, it is possible to provide a coloring composition capable of forming a cured film having excellent light fastness, and it is also possible to provide a cured film having excellent light fastness, a structure, a color filter, a solid-state imaging element, and an image display device.

### DESCRIPTION OF THE PREFERRED EMBODIMENTS

Hereinafter, the contents of the present invention will be described in detail.

In citations for a group (atomic group) in the present specification, in a case where the group is denoted without specifying whether it is substituted or unsubstituted, the group includes both a group having no substituent and a group having a substituent. For example, an “alkyl group” includes not only an alkyl group having no substituent (unsubstituted alkyl group), but also an alkyl group having a substituent (substituted alkyl group).

In the present specification, “exposure” includes, unless otherwise specified, not only exposure using light but also lithography using particle rays such as electron beams and ion beams. In addition, examples of light used for the exposure generally include actinic rays or radiation such as a bright line spectrum of a mercury lamp, far ultraviolet rays typified by an excimer laser, extreme ultraviolet rays (EUV light), X-rays, electron beams, or the like.

In the present specification, a numerical range expressed using “to” means a range that includes the preceding and succeeding numerical values of “to” as the lower limit value and the upper limit value, respectively.

In the present specification, the total solid content refers to a total amount of the components other than a solvent from all the components of a composition.

In the present specification, “(meth)acrylate” represents either or both of acrylate and methacrylate, “(meth)acryl” represents either or both of acryl and methacryl, “(meth)allyl” represents either or both of allyl and methallyl, and “(meth)acryloyl” represents either or both of acryloyl and methacryloyl.

In the present specification, a term “step” not only means an independent step, but also includes a step which is not clearly distinguished from other steps in a case where an intended action of the step is obtained.

In the present specification, a weight-average molecular weight (Mw) and a number-average molecular weight (Mn) are each defined as a value in terms of polystyrene through measurement by means of gel permeation chromatography (GPC).

<Coloring Composition>

The coloring composition of the embodiment of the present invention is a coloring composition including a pigment, a resin, and a curable compound, in which the pigment includes a red pigment, a yellow pigment, and an orange pigment, and a mass ratio of the yellow pigment to the red pigment and a mass ratio of the orange pigment to the red pigment in the coloring composition are yellow pigment/red pigment=1.0 to 2.0/1.0 and orange pigment/red pigment=0.9 to 2.0/1.0, respectively. By the coloring composition of the embodiment of the present invention, it is possible to form a cured film having excellent light fastness. A reason for obtaining such an effect is presumed to be as follows.

A cause for a reduction in light fastness in a cured film including a pigment is presumed to be deterioration of the pigment since radicals generated by light energy irradiated onto the cured film attack the pigment. In particular, the yellow pigment is easily attacked by the radicals and the yellow pigment is easily discolored. In contrast, in the present invention, by incorporation of the red pigment, the orange pigment, and the yellow pigment at a predetermined ratio as described above, movement of light energy among the respective pigments occurs even upon irradiation of light onto the cured film, the light energy emits, and thus, generation of radicals can be suppressed, which is presumed to lead to formation of a cured film having excellent light fastness. Hereinafter, the respective components of the coloring composition of the embodiment of the present invention will be described.

<<Pigment>>

The coloring composition of the embodiment of the present invention includes a red pigment, a yellow pigment, and an orange pigment as a pigment.

In the present invention, the red pigment preferably has a maximum absorption wavelength in a range of 350 to 600 nm, more preferably has the maximum absorption wavelength in a range of 420 to 600 nm, still more preferably has the maximum absorption wavelength in a range of 520 to 580 nm, and particularly preferably has the maximum absorption wavelength in a range of 550 to 560 nm. Further, the lowest value of a color value of the red pigment in a wavelength range of 400 to 570 nm is preferably 0.5 or more, more preferably 0.6 or more, and still more preferably 0.7 or more.

The color value at the maximum absorption wavelength of red pigment is preferably 5 or more, more preferably 7 or more, and still more preferably 10 or more. The upper limit is not particularly limited, and is preferably 100 or less. In a case where the color value of the red pigment is 10 or more, it is possible to further reduce the amount of the yellow pigment required to obtain an appropriate wave form in red pixels or the like of a color filter to a value in the above-mentioned range, and further enhance the light fastness. Further, in the present invention, the color value of the pigment is a value calculated from the following equation by measuring an absorbance at a maximum absorption wavelength of a film including a pigment to be measured.

Color value of a pigment=Absorbance at a maximum absorption wavelength of a film including a pigment to be measured pigment÷Pigment concentration (% by mass) in the film÷Film thickness (m)

Examples of the red pigment include a diketopyrrolopyrrole compound, an azo compound, an azomethine compound, a xanthene compound, an anthraquinone compound, a thioindigo compound, a quinacridone compound, a perylene compound, a perinone compound, a benzimidazolone compound, and an isoindoline compound, the diketopyrrolopyrrole compound, the quinacridone compound, the anthraquinone compound, the perylene compound, or the azo compound is preferable, and for a reason that the dispersion stability is excellent, the diketopyrrolopyrrole compound is more preferable.

Specific examples of the red pigment include Color Index (C. I.) Pigment Red 1, 2, 3, 4, 5, 6, 7, 9, 10, 14, 17, 22, 23, 31, 38, 41, 48:1, 48:2, 48:3, 48:4, 49, 49:1, 49:2, 52:1, 52:2, 53:1, 57:1, 60:1, 63:1, 66, 67, 81:1, 81:2, 81:3, 83, 88, 90, 105, 112, 119, 122, 123, 144, 146, 149, 150, 155, 166, 168, 169, 170, 171, 172, 175, 176, 177, 178, 179, 184, 185, 187, 188, 190, 200, 202, 206, 207, 208, 209, 210, 216, 220, 224, 226, 242, 246, 254, 255, 264, 270, 272, and 279, and C. I. Pigment Red 177, 254, and 264 are preferable. Among those, C. I. Pigment Red 254 is more preferable since it has a high color value and excellent dispersion stability.

In the present invention, the orange pigment preferably has a maximum absorption wavelength in a range of 350 to 550 nm, more preferably has the maximum absorption wavelength in a range of 400 to 550 nm, still more preferably has the maximum absorption wavelength in a range of 420 to 500 nm, and particularly preferably has the maximum absorption wavelength in a range of 440 to 460 nm. Further, the lowest value of a color value in a wavelength range of 400 to 550 nm of the orange pigment is preferably 0.3 or more, more preferably 0.4 or more, and still more preferably 0.5 or more.

The color value at the maximum absorption wavelength of the orange pigment is preferably 1 or more, more preferably 1.5 or more, and still more preferably 2 or more. The upper limit is not particularly limited, and is preferably 100 or less. In a case where the color value of the orange pigment is 2 or more, higher excitation energy of the yellow pigment can be obtained, and thus, it is possible to expect an effect of enhancing the light fastness of the yellow pigment.

Examples of the orange pigment include a diketopyrrolopyrrole compound, an azo compound, an azomethine compound, a pyrazolone compound, a benzimidazolone compound, an anthraquinone compound, a perinone compound, a quinacridone compound, an isoindolinone compound, an isoindoline compound, a pyranthrone compound, and a phenanthroline compound, the diketopyrrolopyrrole compound, the azo compound, the pyranthrone compound, the pyrazolone compound, or the phenanthroline compound is preferable, and for a reason that the dispersion stability is excellent, the diketopyrrolopyrrole compound is more preferable.

Specific examples of the orange pigment include C. I. Pigment Orange 2, 5, 13, 16, 17:1, 31, 34, 36, 38, 43, 46, 48, 49, 51, 52, 55, 59, 60, 61, 62, 64, 71, and 73, and C. I. Pigment Orange 38, 71, 36, 43, 51, 55, 59, 61, or 73 is preferable. Among those, for a reason that the color value is high and the dispersion stability is excellent, C. I. Pigment Orange 71 is more preferable.

In the present invention, the yellow pigment preferably has a maximum absorption wavelength in a range of 350 to 500 nm, more preferably has a maximum absorption wavelength in a range of 400 to 500 nm, still more preferably has a maximum absorption wavelength in a range of 420 to 500 nm, and particularly preferably has a maximum absorption wavelength in a range of 450 to 500 nm. Further, the lowest value of a color value in a wavelength range of 400 to 470 nm of the yellow pigment is preferably 0.5 or more, more preferably 1 or more, and still more preferably 1.5 or more.

The color value at the maximum absorption wavelength of the yellow pigment is preferably 3 or more, more preferably 4 or more, and still more preferably 5 or more. The upper limit is not particularly limited, and is preferably 100 or less. In a case where the color value of the yellow pigment is 5 or more, it is possible to further reduce the amount of the yellow pigment required to obtain an appropriate wave form in red pixels or the like of a color filter to a value in the above-mentioned range, and further enhance the light fastness.

Examples of the yellow pigment include an azo compound, a pyrazolone compound, a benzimidazolone compound, a quinoxaline compound, an azomethine compound, a quinophthalone compound, an isoindolinone compound, an isoindoline compound, an anthraquinone compound, a pyranthrone compound, and a phenanthroline compound, the isoindoline compound, the azo compound, the pyranthrone compound, the pyrazolone compound, the phenanthroline compound, or the quinophthalone compound is preferable, the isoindoline compound, the azo compound, or the quinophthalone compound is more preferable, and for a reason that the dispersion stability is excellent, the isoindoline compound is more preferable.

Specific examples of the yellow pigment include C. I. Pigment Yellow 1, 2, 3, 4, 5, 6, 10, 11, 12, 13, 14, 15, 16, 17, 18, 20, 24, 31, 32, 34, 35, 35:1, 36, 36:1, 37, 37:1, 40, 42, 43, 53, 55, 60, 61, 62, 63, 65, 73, 74, 77, 81, 83, 86, 93, 94, 95, 97, 98, 100, 101, 104, 106, 108, 109, 110, 113, 114, 115, 116, 117, 118, 119, 120, 123, 125, 126, 127, 128, 129, 137, 138, 139, 147, 148, 150, 151, 152, 153, 154, 155, 156, 161, 162, 164, 166, 167, 168, 169, 170, 171, 172, 173, 174, 175, 176, 177, 179, 180, 181, 182, 185, 187, 188, 193, 194, 199, 213, and 214, and C. I. Pigment Yellow 139, 150, or 185 is preferable. Among those, for a reason that the color value is high and the dispersion stability is excellent, C. I. Pigment Yellow 139 is more preferable.

In the present invention, a combination of a red pigment which is C. I. Pigment Red 254, an orange pigment which is C. I. Pigment Orange 71, and a yellow pigment which is C. I. Pigment Yellow 139 is particularly preferable. With such a combination, a cured film having excellent light fastness is easily formed. In addition, since each of coloring materials has a high color value and the amount of the pigments required to obtain the same absorbance, it is possible to expect an effect that patterning properties in photolithography are excellent.

The coloring composition of the embodiment of the present invention can contain pigments (other pigments) other than the red pigment, the yellow pigment, and the orange pigment, as the pigment. Examples of such other pigments include a green pigment, a violet pigment, and a blue pigment. Examples of the green pigment include C. I. Pigment Green 7, 10, 36, 37, 58, and 59. Examples of the violet pigment include C. I. Pigment Violet 1, 19, 23, 27, 32, 37, 42, 58, and 59. Examples of the blue pigment include C. I. Pigment Blue 1, 2, 15, 15:1, 15:2, 15:3, 15:4, 15:6, 16, 22, 60, 64, 66, 79, and 80. Further, a halogenated zinc phthalocyanine pigment having an average number of halogen atoms in one molecule of 10 to 14, an average number of bromine atoms in one molecule of 8 to 12, and an average number of chlorine atoms in one molecule of 2 to 5 can also be used as the green pigment. Specific examples thereof include the compounds described in WO2015/118720A. Further, an aluminumphthalocyanine compound having a phosphorus atom can also be used as the blue pigment. Specific examples thereof include the compounds described in paragraph Nos. 0022 to 0030 of JP2012-247591A and paragraph No. 0047 of JP2011-157478A.

In the coloring composition of the embodiment of the present invention, the mass ratio of the yellow pigment to the red pigment (yellow pigment/red pigment) is 1.0 to 2.0/1.0, preferably 1.1 to 1.9/1.0, more preferably 1.3 to 1.7/1.0, an still more preferably 1.4 to 1.6/1.0. Further, the mass ratio of the orange pigment to the red pigment (orange pigment/red pigment) is 0.9 to 2.0/1.0, preferably 1.1 to 1.9/1.0, more preferably 1.3 to 1.7/1.0, and still more preferably 1.4 to 1.6/1.0. In a case where the mass ratio of the yellow pigment to the red pigment and the mass ratio of the orange pigment to the red pigment are within the ranges, it is possible to form a cured film having excellent light fastness.

In the coloring composition of the embodiment of the present invention, the content of the pigment is preferably 10% to 99% by mass with respect to the total solid content of the coloring composition. The lower limit is more preferably 40% by mass or more, and still more preferably 50% by mass or more. The upper limit is more preferably 90% by mass or less, and still more preferably 80% by mass or less. Further, the total amount of the red pigment, the orange pigment, and the yellow pigment in the total mass of the pigment is preferably 50% to 100% by mass, more preferably 70% to 100% by mass, and still more preferably 90% to 100% by mass. In a case where the total amount of the red pigment, the orange pigment, and the yellow pigment is 50% by mass or more, it is possible to form a cured film having excellent light fastness and preferred spectral characteristics suitable for red pixels of a color filter.

<<Dye>>

The coloring composition of the embodiment of the present invention can contain a dye as such another coloring agent. Examples of the dye include the dyes disclosed in JP1989-090403A (JP-S64-090403A), JP1989-091102A (JP-S64-091102A), JP1989-094301A (JPH01-094301A), JP1994-011614A (JP-H06-011614A), U.S. Pat. No. 4,808,501B, US0505950B, U.S. Pat. No. 5,667,920B, JP1993-333207A (JP-H05-333207A), JP1994-035183A (JP-H06-035183A), JP1994-051115A (JP-H06-051115A), and JP1994-194828A (JP-H06-194828A). In terms of classification based on the chemical structure, examples of the dye include a pyrazoleazo compound, a pyrromethene compound, an anilinoazo compound, a triarylmethane compound, an anthraquinone compound, a benzylidene compound, an oxonol compound, a pyrazolotriazoleazo compound, a pyridoneazo compound, a cyanine compound, a phenothiazine compound, and a pyrrolopyrazoleazomethine compound. Moreover, as the coloring agent, a dye multimer can be used. The dye multimer is preferably a dye that is used after being dissolved in a solvent, but the dye multimer may form a particle. In a case where the dye multimer is the particle, it is usually used in a state of being dispersed in a solvent or the like. The dye multimer in the particle state can be obtained by, for example, emulsion polymerization. Examples of the dye multimer in the state of particles include the compounds described in JP2015-214682A. In addition, as the dye multimer, the compounds described in JP2011-213925A, JP2013-041097A, JP2015-028144A, JP2015-030742A, or the like can also be used.

The content of the dye is preferably 90% by mass or less, more preferably 50% by mass or less, and still more preferably 10% by mass or less, with respect to the total solid content in the coloring composition. The lower limit can be set to, for example, 1% by mass or more.

Furthermore, the content of the dye is preferably 50 parts by mass or less, more preferably 30 parts by mass or less, and still more preferably 10 parts by mass or less, with respect to 100 parts by mass of a sum of the red pigment, the orange pigment, and the yellow pigment. The lower limit can be set to, for example, 1 part by mass or more.

In addition, it is also preferable that the coloring composition of the embodiment of the present invention substantially does not contain a dye. The expression, the coloring composition substantially not containing a dye, means that the content of the dye is preferably 0.5% by mass or less, and more preferably 0.1% by mass or less, with respect to the total solid content in the coloring composition, and particularly, the dye is not contained.

<<Resin>>

The coloring composition of the embodiment of the present invention includes a resin. The resin is blended in applications, such as an application for dispersing particles such as a pigment in the composition or an application as a binder. Incidentally, a resin which is usually used for dispersing particles such as a pigment is also referred to as a dispersant. However, such applications of the resin are only exemplary, and the resin can also be used for other purposes, in addition to the above-mentioned applications.

In the coloring composition of the embodiment of the present invention, the content of the resin is preferably 1% to 80% by mass with respect to the total solid content of the coloring composition. The lower limit is more preferably 10% by mass or more, and still more preferably 20% by mass or more. The upper limit is more preferably 60% by mass or less, and still more preferably 40% by mass or less.

(Dispersant)

The coloring composition of the embodiment of the present invention preferably contains a dispersant as the resin. Examples of the dispersant include an acidic dispersant (acidic resin) and a basic dispersant (basic resin). Here, the acidic dispersant (acidic resin) represents a resin in which the amount of acid groups is more than that of basic groups. As the acidic dispersant (acidic resin), a resin in which the amount of the acid groups is 70% by mole or more with respect to 100% by mole of the total amount of the acid groups and the basic groups is preferable, and a resin which is only substantially composed of acid groups is more preferable. The acid group contained in the acidic dispersant (acidic resin) is preferably a carboxyl group. The acid value of the acidic dispersant (acidic resin) is preferably 5 to 105 mgKOH/g. Furthermore, the basic dispersant (basic resin) is a resin in which the amount of acid groups is more than that of basic groups. As the basic dispersant (basic resin), a resin in which the amount of the basic groups is more than 50% by mole with respect to 100% by mole of the total amount of the acid groups and the basic groups is preferable. The basic group contained in the basic dispersant is preferably an amino group.

Examples of the dispersant include a polymer dispersant [for example, a polyamidoamine and a salt thereof, a polycarboxylic acid and a salt thereof, a high-molecular-weight unsaturated acid ester, a modified polyurethane, a modified polyester, a modified poly(meth)acrylate, a (meth)acrylic copolymer, and a naphthalene sulfonic acid/formalin polycondensate], a polyoxyethylene alkyl phosphoric acid ester, a polyoxyethylene alkylamine, and an alkanolamine.

The polymer dispersants can further be classified into a linear polymer, a terminal-modified polymer, a graft type polymer, and a block type polymer, depending on its structure. The polymer dispersant is adsorbed on a surface of a pigment, and thus, acts to prevent re-aggregation. For this reason, examples of a preferable structure thereof include a terminal-modified polymer, a graft-type polymer, and a block-type polymer, which have an anchoring site for the surface of a pigment. Incidentally, the dispersants described in paragraph Nos. 0028 to 0124 of JP2011-070156A or the dispersants described in JP2007-277514A are also preferably used, the contents of which are incorporated herein by reference.

In the present invention, as the resin, a resin including a repeating unit having a graft chain in a side chain thereof (hereinafter also referred to as a graft resin) is preferably used. According to this aspect, the dispersibility of the pigment can be further improved. Here, the graft chain means a polymer chain that is branched and elongated from the main chain of a repeating unit. The length of the graft chain is not particularly limited, and in a case where the graft chain gets longer, a steric repulsion effect is enhanced, and thus, the dispersibility of a pigment or the like can be increased. In the graft chain, the number of atoms excluding the hydrogen atoms is preferably 40 to 10,000, the number of atoms excluding the hydrogen atoms is more preferably 50 to 2,000, and the number of atoms excluding the hydrogen atoms is still more preferably 60 to 500.

The graft chain preferably includes at least one selected from a polyester chain, a polyether chain, a poly(meth)acryl chain, a polyurethane chain, a polyurea chain, and a polyamide chain, more preferably includes at least one selected from a polyester chain, a polyether chain, and a poly(meth)acryl chain, and still more preferably includes a polyester chain.

The terminal structure of the graft chain is not particularly limited, and may be either a hydrogen atom or a substituent. Examples of the substituent include an alkyl group, an aryl group, a heteroaryl group, an alkoxy group, an aryloxy group, a heteroaryloxy group, an alkylthioether group, an arylthioether group, and a heteroarylthioether group. Among those, from the viewpoint of improving the dispersibility of a pigment or the like, a group having a steric repulsion effect is preferable, and an alkyl group or alkoxy group having 5 to 24 carbon atoms is preferable. The alkyl group and the alkoxy group may be any of linear, branched, and cyclic forms, and are preferably linear or branched.

As the graft resin, a resin including a repeating unit having a polyester chain in a side chain is preferable, and a resin including a repeating unit represented by any one of Formula (I) and Formula (II) is more preferable.

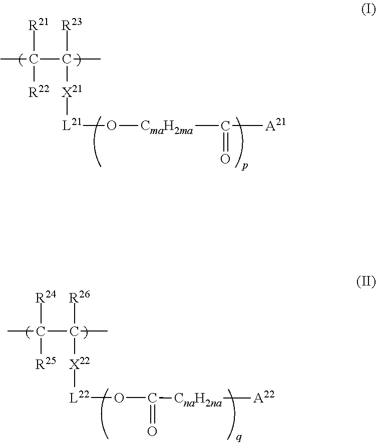

In Formula (I) and Formula (II), R²¹ to R²⁶ each independently represent a hydrogen atom or an alkyl group, X²¹ and X²² each independently represent —CO—, —C(═O)O—, —CONH—, —OC(═O)—, or a phenylene group, L²¹ and L²² each independently represent a single bond or a divalent linking group, A²¹ and A²² each independently represent a hydrogen atom or a substituent, ma and na each independently represent an integer of 2 to 8, and p and q each independently represent an integer of 1 to 100.

The number of carbon atoms of the alkyl group represented by each of R²¹ to R²⁶ is preferably 1 to 12, more preferably 1 to 8, still more preferably 1 to 4, and particularly preferably 1. R²¹, R²², R²⁴, and R²⁵ are each preferably a hydrogen atom. Further, R²³ and R²⁶ are each preferably a hydrogen atom or a methyl group.

X²¹ and X²² each independently represent —CO—, —C(═O)O—, —CONH—, —OC(═O)—, or a phenylene group. Among those, from the viewpoint of adsorption properties for a pigment, —C(═O)O—, —CONH—, or a phenylene group is preferable, and —C(═O)O— is more preferable.

Examples of the divalent linking group represented by each of L²¹ and L²² include an alkylene group (preferably an alkylene group having 1 to 12 carbon atoms), an arylene group (preferably an arylene group having 6 to 20 carbon atoms), —NH—, —SO—, —SO2-, —CO—, —O—, —COO—, OCO—, —S—, and a group formed by combination of two or more of these groups.

Examples of the substituent represented by each of A²¹ and A²² include an alkyl group, an aryl group, a heteroaryl group, an alkoxy group, an aryloxy group, a heteroaryloxy group, an alkylthioether group, an arylthioether group, and a heteroarylthioether group. Among those, from the viewpoint of improving the dispersibility of the pigment, a group having a steric repulsion effect is preferable, a linear alkyl group having 1 to 20 carbon atoms, a branched alkyl group having 3 to 20 carbon atoms, or a cyclic alkyl group having 5 to 20 carbon atoms is preferable, a linear alkyl group having 4 to 15 carbon atoms, a branched alkyl group having 4 to 15 carbon atoms, or a cyclic alkyl group having 6 to 10 carbon atoms is more preferable, and a linear alkyl group having 6 to 10 carbon atoms or a branched alkyl group having 6 to 12 carbon atoms is still more preferable.

ma and na each independently represent an integer of 2 to 8. In views of dispersion stability and developability, ma and na are each independently preferably 4 to 6.

p and q each independently represent an integer of 1 to 100. In a case where p is 2 or more, a plurality of ma's may be the same as or different from each other. Further, in a case where q is 2 or more, a plurality of na's may be the same as or different from each other.

With regard to details of the graft resin, reference can be made to the description in paragraph Nos. 0025 to 0094 of JP2012-255128A, the contents of which are incorporated herein by reference. Further, specific examples of the graft resin include the following resins and the resins described in paragraph Nos. 0072 to 0094 of JP2012-255128A, the contents of which are incorporated herein by reference.

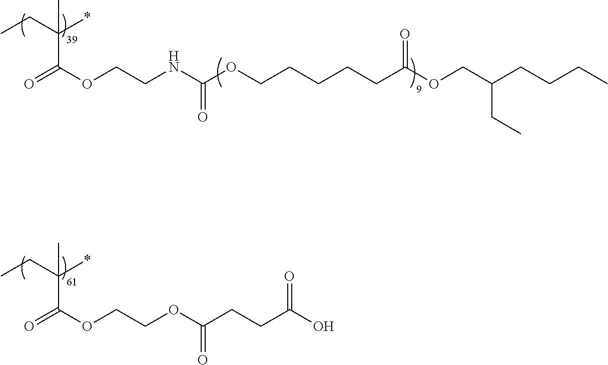

Furthermore, in the present invention, an oligoimine-based resin including a nitrogen atom in at least one of the main chain or a side chain can be used as the resin. The oligoimine-based resin is preferably a repeating unit having a nitrogen atom, which is at least one selected from a poly(lower alkylenimine)-based repeating unit, a polyallylamine-based repeating unit, a polydiallylamine-based repeating unit, a methaxylenediamine-epichlorohydrin polycondensate-based repeating unit, or a polyvinylamine-based repeating unit. With regard to the oligoimine-based resin, reference can be made to the description in paragraph Nos. 0102 to 0174 of JP2012-255128A, the contents of which are incorporated herein by reference. Specific examples of the oligoimine-based resin include the resins described in paragraph Nos. 0168 to 0174 of JP2012-255128A.

For the resin as a dispersant, a commercially available product can also be used. For example, the products described in paragraph No. 0129 of JP2012-137564A can also be used as a dispersant. Examples of the products include Disperbyk-111 (manufactured by BYK Chemie). Further, the resin described as the dispersant can also be used in applications other than the dispersant. For example, the resin can also be used as a binder.

The content of the dispersant is preferably 1 to 200 parts by mass with respect to 100 parts by mass of the pigment. The lower limit is preferably 5 parts by mass or more, and more preferably 10 parts by mass or more. The upper limit is more preferably 150 parts by mass or less, and more preferably 100 parts by mass or less.

(Alkali-Soluble Resin)

The coloring composition of the embodiment of the present invention can contain an alkali-soluble resin as the resin. By incorporation of the alkali-soluble resin, the developability or the pattern formability is improved. Further, the alkali-soluble resin can also be used as a dispersant or a binder.

The alkali-soluble resin can be appropriately selected from resins having a group enhancing alkali-solubility. Examples of the group enhancing alkali-solubility (hereinafter also referred to as an acid group) include a carboxyl group, a phosphoric acid group, a sulfo group, and a phenolic hydroxyl group, and the group is preferably the carboxyl group. The alkali-soluble resin may have one kind or two or more kinds of the acid groups.

The weight-average molecular weight (Mw) of the alkali-soluble resin is preferably 5,000 to 100,000. Further, the number-average molecular weight (Mn) of the alkali-soluble resin is preferably 1,000 to 20,000.

As the alkali-soluble resin, from the viewpoint of heat resistance, a polyhydroxystyrene-based resin, a polysiloxane-based resin, an acrylic resin, an acrylamide-based resin, and an acryl/acrylamide copolymer resin are preferable. Further, from the viewpoint of controlling developability, an acrylic resin, an acrylamide-based resin, or an acryl/acrylamide copolymer resin is preferable.

As the alkali-soluble resin, a polymer having a carboxyl group in a side chain is preferable. Examples thereof include copolymers having a repeating unit derived from monomers such as methacrylic acid, acrylic acid, itaconic acid, crotonic acid, maleic acid, 2-carboxyethyl (meth)acrylic acid, vinylbenzoic acid, and a partially esterified maleic acid, an alkali-soluble phenol resin such as a novolac resin, an acidic cellulose derivative having a carboxyl group in a side chain, and a polymer obtained by adding an acid anhydride to a polymer having a hydroxyl group. In particular, a copolymer of a (meth)acrylic acid and another monomer copolymerizable with the (meth)acrylic acid is suitable as the alkali-soluble resin. Examples of another monomer copolymerizable with a (meth)acrylic acid include alkyl (meth)acrylate, aryl (meth)acrylate, and a vinyl compound. Examples of the alkyl (meth)acrylate and the aryl (meth)acrylate include methyl (meth)acrylate, ethyl (meth)acrylate, propyl (meth)acrylate, butyl (meth)acrylate, isobutyl (meth)acrylate, pentyl (meth)acrylate, hexyl (meth)acrylate, octyl (meth)acrylate, phenyl (meth)acrylate, benzyl (meth)acrylate, tolyl (meth)acrylate, naphthyl (meth)acrylate, cyclohexyl (meth)acrylate, glycidyl methacrylate, and tetrahydrofurfuryl methacrylate. Examples of the vinyl compound include styrene, α-methylstyrene, vinyltoluene, acrylonitrile, vinyl acetate, N-vinylpyrrolidone, a polystyrene macromonomer, and a polymethyl methacrylate macromonomer. Further, examples of other monomer include the N-position-substituted maleimide monomers described in JP1998-300922A (JP-H10-300922A), such as N-phenylmaleimide and N-cyclohexylmaleimide. Such other monomers copolymerizable with (meth)acrylic acids may be of one kind or of two or more kinds thereof.

As the alkali-soluble resin, a benzyl (meth)acrylate/(meth)acrylic acid copolymer, a benzyl (meth)acrylate/(meth)acrylic acid/2-hydroxyethyl (meth)acrylate copolymer, or a multicomponent copolymer including benzyl (meth)acrylate/(meth)acrylic acid/other monomers can be preferably used. Further, a copolymer obtained by copolymerizing 2-hydroxyethyl (meth)acrylate and other monomers, the 2-hydroxypropyl (meth)acrylate/polystyrene macromonomer/benzyl methacrylate/methacrylic acid copolymer described in JP1995-140654A (JP-H07-140654A), a 2-hydroxy-3-phenoxypropylacrylate/polymethyl methacrylate macromonomer/benzyl methacrylate/methacrylic acid copolymer, a 2-hydroxyethyl methacrylate/polystyrene macromonomer/methyl methacrylate/methacrylic acid copolymer, a 2-hydroxyethyl methacrylate/polystyrene macromonomer/benzyl methacrylate/methacrylic acid copolymer, and the like can also be preferably used. In addition, as a commercially available product thereof, for example, FF-426 (manufactured by Fujikura Kasei Co., Ltd.) or the like can also be used.

As the alkali-soluble resin, an alkali-soluble resin having a polymerizable group can also be used. Examples of the polymerizable group include a (meth)allyl group and a (meth)acryloyl group. As the alkali-soluble resin having a polymerizable group, an alkali-soluble resin having a polymerizable group on a side chain thereof, and the like are useful. Examples of commercially available products of the alkali-soluble resin having a polymerizable group include DIANAL NR Series (manufactured by Mitsubishi Rayon Co., Ltd.), PHOTOMER 6173 (carboxyl group-containing polyurethane acrylic oligomer, manufactured by Diamond Shamrock Co., Ltd.), VISCOAT R-264 and KS RESIST 106 (both manufactured by Osaka Organic Chemical Industry, Ltd.), CYCLOMER P Series (for example, ACA230AA) and PLACCEL CF200 Series (both manufactured by Daicel Corporation), Ebecryl 3800 (manufactured by Daicel-UCB Co., Ltd.), ACRYCURE RD-F8 (manufactured by Nippon Shokubai Co., Ltd.), and DP-1305 (manufactured by Fujifilm Fine Chemicals Co., Ltd.).

It is also preferable that the alkali-soluble resin includes a polymer formed by polymerizing monomer components including at least one compound selected from a compound represented by Formula (ED1) or the compound represented by Formula (1) of JP2010-168539A (these compounds are hereinafter also referred to as an “ether dimer” in some cases).

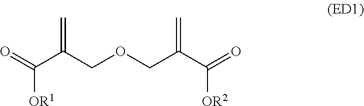

In Formula (ED1), R¹ and R² each independently represent a hydrogen atom or a hydrocarbon group having 1 to 25 carbon atoms, which may have a substituent.

With regard to specific examples of the ether dimer, reference can be made to paragraph No. 0317 of JP2013-029760A, the contents of which are incorporated herein by reference. These ether dimers may be of one kind or of two or more kinds.

Examples of the polymer formed by polymerization of monomer components including ether dimers include polymers having the following structures.

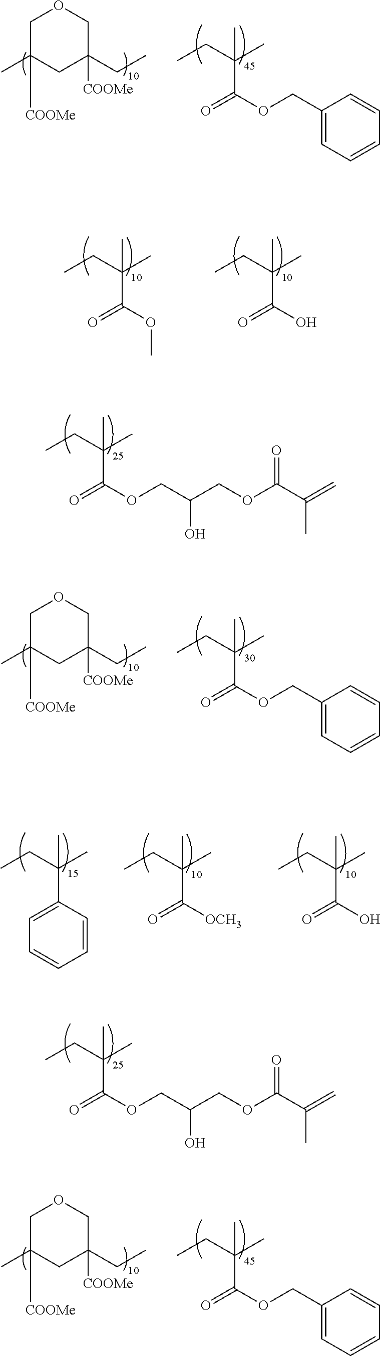

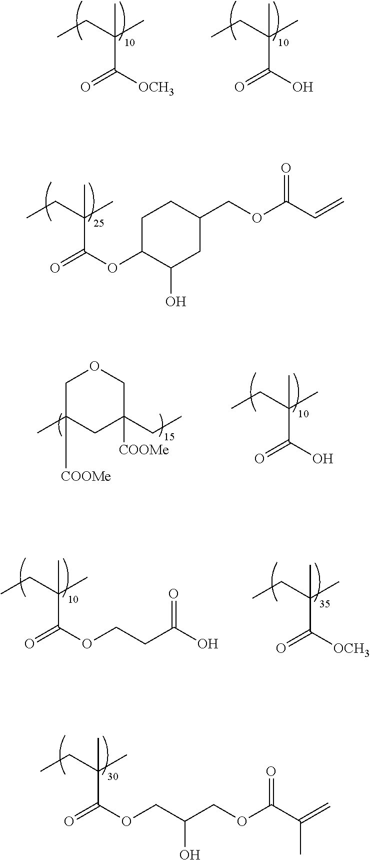

The alkali-soluble resin may include a repeating unit derived from a compound represented by Formula (X).

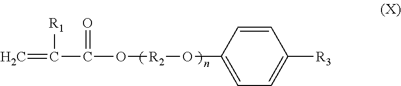

In Formula (X), R₁ represents a hydrogen atom or a methyl group, R₂ represents an alkylene group having 2 to 10 carbon atoms, and R₃ represents a hydrogen atom or an alkyl group having 1 to 20 carbon atoms, which may include a benzene ring. n represents an integer of 1 to 15.

In Formula (X), the number of carbon atoms in the alkylene group of R₂ is preferably 2 or 3. Further, the number of carbon atoms in the alkyl group of R₃ is preferably 1 to 10. The alkyl group of R₃ may include a benzene ring. Examples of the alkyl group including a benzene ring, represented by R₃, include a benzyl group and a 2-phenyl(iso)propyl group.

With regard to the alkali-soluble resin, reference can be made to the description in paragraph Nos. 0558 to 0571 of JP2012-208494A (paragraph Nos. 0685 to 0700 of the corresponding US2012/0235099A), the contents of which are incorporated herein by reference. In addition, the copolymers (B) described in paragraph Nos. 0029 to 0063 of JP2012-032767A and the alkali-soluble resins used in Examples of the document, the binder resins described in paragraph Nos. 0088 to 0098 of JP2012-208474A and the binder resins used in Examples of the document, the binder resins described in paragraph Nos. 0022 to 0032 of JP2012-137531A and the binder resins used in Examples of the document, the binder resins described in paragraph Nos. 0132 to 0143 of JP2013-024934A and Examples of the document, the binder resins described in paragraph Nos. 0092 to 0098 of JP2011-242752A and the binder resins used in Examples of the document, or the binder resins described in paragraph Nos. 0030 to 0072 of JP2012-032770A can be used, and the contents of these publications are incorporated herein by reference.

The acid value of the alkali-soluble resin is preferably 30 to 500 mgKOH/g. The lower limit is more preferably 50 mgKOH/g or more, and still more preferably 70 mgKOH/g or more. The upper limit is more preferably 400 mgKOH/g or less, still more preferably 200 mgKOH/g or less, even still more preferably 150 mgKOH/g or less, and further still more preferably 120 mgKOH/g or less.

The content of the alkali-soluble resin is preferably 1% to 80% by mass with respect to the total solid content of the coloring composition. The lower limit is more preferably 10% by mass or more, and still more preferably 20% by mass or more. The upper limit is more preferably 60% by mass or less, and still more preferably 40% by mass or less. The coloring composition of the embodiment of the present invention may include one kind or two or more kinds of the alkali-soluble resins. In a case where two or more kinds of the alkali-soluble resins are included, the total amount thereof is preferably within the range.

(Other Resins)

The coloring composition of the embodiment of the present invention can contain resins (which are also referred to as other resins) other than the resins described in the section of the dispersant or the alkali-soluble resin as described above. Examples of such other resins include a (meth)acryl resin, a (meth)acrylamide resin, an ene-thiol resin, a polycarbonate resin, a polyether resin, a polyarylate resin, a polysulfone resin, a polyethersulfone resin, a polyphenylene resin, a polyarylene ether phosphine oxide resin, a polyimide resin, a polyamideimide resin, a polyolefin resin, a cyclic olefin resin, a polyester resin, a styrene resin, and a siloxane resin. Such other resins may be used singly or in mixture of two or more kinds of those resins.

<<Curable Compound>>

The coloring composition of the embodiment of the present invention contains a curable compound. As the curable compound, a known compound which can be crosslinked by a radical, an acid, or heat can be used. In the present invention, examples of the curable compound include a compound having ethylenically unsaturated bond groups and a compound having an epoxy group, and the compound having ethylenically unsaturated bond groups is preferable. Examples of the compound having ethylenically unsaturated bond groups include a vinyl group, a (meth)allyl group, and a (meth)acryloyl group. The compound having ethylenically unsaturated bond groups is preferably a polymerizable compound, and more preferably a radically polymerizable compound.

In the coloring composition of the embodiment of the present invention, the content of the curable compound is preferably 0.1% to 50% by mass with respect to the total solid content of the coloring composition. The lower limit is, for example, more preferably 0.5% by mass or more, and still more preferably 1% by mass or more. The upper limit is, for example, more preferably 45% by mass or less, and still more preferably 40% by mass or less. The curable compound may be used singly or in combination of two or more kinds thereof. In a case where two or more kinds of the curable compounds are included, the total amount thereof is preferably within the range.

(Compound Having Ethylenically Unsaturated Bond Groups)

The compound having ethylenically unsaturated bond groups may be, for example, any of chemical forms such as a monomer, a prepolymer, and an oligomer, but the monomer is preferable. The molecular weight of the compound having ethylenically unsaturated bond groups is preferably 100 to 3,000. The upper limit is more preferably 2,000 or less, and still more preferably 1,500 or less. The lower limit is more preferably 150 or more, and still more preferably 250 or more.

The compound having ethylenically unsaturated bond groups is preferably a compound including 3 or more ethylenically unsaturated bond groups, more preferably a compound including 3 to 15 ethylenically unsaturated bond groups, and still more preferably a compound including 3 to 6 ethylenically unsaturated bond groups. In addition, compound having ethylenically unsaturated bond groups is preferably a trifunctional to pentadecafunctional (meth)acrylate compound, and more preferably a trifunctional to hexafunctional (meth)acrylate compound.

Furthermore, the compound including 3 or more ethylenically unsaturated bond groups is preferably a compound having an alkyleneoxy group. By using such a compound, appropriate flexibility can be imparted onto a cured film, and thus, pattern damages, peeling, or the like during development can be suppressed, and the adhesiveness or film residual rates after development can be increased.

Examples of the compound having ethylenically unsaturated bond groups and an alkyleneoxy group include a compound represented by Formula (M-1).

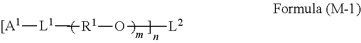

In the formula, A¹ represents an ethylenically unsaturated bond group, L¹ represents a single bond or a divalent linking group, R¹ represents an alkylene group, m represents an integer of 1 to 30, n represents an integer of 3 or more, and L² represents an n-valent linking group.

Examples of the ethylenically unsaturated bond group represented by A¹ include a vinyl group, a (meth)allyl group, and a (meth)acryloyl group, and the (meth)acryloyl group is preferable.

Examples of the divalent linking group represented by L¹ include an alkylene group, an arylene group, —O—, —CO—, —COO—, —OCO—, —NH—, and a group formed by combination of two or more of these groups. The number of carbon atoms of the alkylene group is preferably 1 to 30, more preferably 1 to 20, and still more preferably 1 to 15. The alkylene group may be in any form of linear, branched, and cyclic forms. The number of carbon atoms of the arylene group is preferably 6 to 30, more preferably 6 to 20, and still more preferably 6 to 10.

The number of carbon atoms of the alkylene group represented by R¹ is preferably 1 to 10, more preferably 1 to 5, still more preferably 1 to 3, particularly preferably 2 or 3, and most preferably 2. The alkylene group represented by R¹ is preferably linear or branched, and more preferably linear. Specific examples of the alkylene represented by R¹ include an ethylene group, and a linear or branched propylene group.

m represents an integer of 1 to 30, and is preferably an integer of 1 to 20, more preferably an integer of 1 to 10, still more preferably an integer of 1 to 5, particularly preferably 1 or 2, and most preferably 1.

n represents an integer of 3 or more, and is preferably an integer of 3 to 15, and more preferably an integer of 3 to 6.

Examples of the n-valent linking group represented by L² include an aliphatic hydrocarbon group, an aromatic hydrocarbon group, a heterocyclic group, and a group formed by combination of these groups, and aliphatic hydrocarbon group, and a group formed by combination of at least one selected from an aromatic hydrocarbon group or a heterocyclic group, and at least one selected from —O—, —CO—, —COO—, —OCO—, or —NH—, and the aliphatic hydrocarbon group is preferable. The number of carbon atoms of the aliphatic hydrocarbon group is preferably 1 to 30, more preferably 1 to 20, and still more preferably 1 to 15. The aliphatic hydrocarbon group represented by L² may be in any form of linear, branched, and cyclic forms, and is preferably branched. The number of carbon atoms of the aromatic hydrocarbon group is preferably 6 to 30, more preferably 6 to 20, and still more preferably 6 to 10. The heterocyclic group may be either a non-aromatic heterocyclic group or an aromatic heterocyclic group. The heterocyclic group is preferably a 5- or 6-membered ring. Examples of the type of a hetero atom constituting the heterocyclic group include a nitrogen atom, an oxygen atom, and a sulfur atom. The number of the hetero atoms constituting the heterocyclic group is preferably 1 to 3. The heterocyclic group may be a monocycle or a fused ring.

As the compound having ethylenically unsaturated bond groups and an alkyleneoxy group, a compound represented by Formula (M-2) is more preferable.

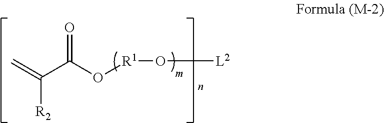

In the formula, R² represents a hydrogen atom or a methyl group, R¹ represents an alkylene group, m represents an integer of 1 to 30, n represents an integer of 3 or more, and L² represents an n-valent linking group. R¹, L², m, and n in Formula (M-2) have the same definitions as R¹, L², m, and n, respectively, in Formula (M-1), and preferred ranges thereof are also the same.

Specific examples of the compound having ethylenically unsaturated bond groups and an alkyleneoxy group include SR-494 which is a tetrafunctional (meth)acrylate having four ethyleneoxy groups, manufactured by Sartomer Co., Inc., and KAYARAD TPA-330, and ARONIX M-350 manufactured by Toagosei Chemical Co., Ltd.

As the compound having ethylenically unsaturated bond groups, dipentaerythritol triacrylate (KAYARAD D-330 as a commercially available product; manufactured by Nippon Kayaku Co., Ltd.), dipentaerythritol tetraacrylate (KAYARAD D-320 as a commercially available product; manufactured by Nippon Kayaku Co., Ltd.), dipentaerythritol penta(meth)acrylate (KAYARAD D-310 as a commercially available product; manufactured by Nippon Kayaku Co., Ltd.), dipentaerythritol hexa(meth)acrylate (KAYARAD DPHA as a commercially available product; manufactured by Nippon Kayaku Co., Ltd., NK Ester A-DPH-12E manufactured by Shin-Nakamura Chemical Co., Ltd.), a compound having a structure in which these (meth)acryloyl groups are bonded via an ethylene glycol and/or propylene glycol residue (for example, SR454 and SR499, commercially available from Sartomer Company, Inc.), or the like can also be used. Furthermore, as the compound having ethylenically unsaturated bond groups, a trifunctional (meth)acrylate compound such as trimethylolpropane tri(meth)acrylate, trimethylolpropane propyleneoxy-modified tri(meth)acrylate, trimethylolpropane ethyleneoxy-modified tri(meth)acrylate, isocyanuric acid ethyleneoxy-modified tri(meth)acrylate, and pentaerythritol tri(meth)acrylate is also preferably used. Examples of commercially available products of the trifunctional (meth)acrylate compound include ARONIX M-309, M-310, M-321, M-350, M-360, M-313, M-315, M-306, M-305, M-303, M-452, and M-450 (manufactured by Toagosei Chemical Co., Ltd.), NK Ester A9300, A-GLY-9E, A-GLY-20E, A-TMM-3, A-TMM-3L, A-TMM-3LM-N, A-TMPT, and TMPT (manufactured by Shin-Nakamura Chemical Co., Ltd.), and KAYARAD GPO-303, TMPTA, THE-330, TPA-330, and PET-30 (manufactured by Nippon Kayaku Co., Ltd.).

As the compound having ethylenically unsaturated bond groups, a compound having an acid group can also be used. By using such the compound, generation of development residues can be suppressed. Examples of the acid group include a carboxyl group, a sulfo group, and a phosphoric acid group, and the carboxyl group is preferable. Examples of a commercially available product of the compound having an acid group include ARONIX M-510 and M-520, and ARONIX TO-2349 (manufactured by Toagosei Chemical Co., Ltd.).

In a case where the compound having ethylenically unsaturated bond groups further has an acid group, a preferred acid value of the compound having ethylenically unsaturated bond groups is preferably 0.1 to 40 mgKOH/g, and more preferably 5 to 30 mgKOH/g. In a case where the acid value of the compound having ethylenically unsaturated bond groups is 0.1 mgKOH/g or more, the solubility in a developer is good, whereas in a case where the acid value is 40 mgKOH/g or less, it is advantageous in production or handling, and in addition, photopolymerization performance is good and the curability is excellent.

A preferred aspect of the compound having ethylenically unsaturated bond groups is a compound further having a caprolactone structure. The compound having a caprolactone structure is commercially available as KAYARAD DPCA series from Nippon Kayaku Co., Ltd., examples of which include DPCA-20, DPCA-30, DPCA-60, and DPCA-120.

As the compound having ethylenically unsaturated bond groups, the urethane acrylates as described in JP1973-041708B (JP-S48-041708B), JP1976-037193A (JP-S51-037193A), JP1990-032293B (JP-H02-032293B), and JP1990-016765B (JP-H02-016765B), and the urethane compounds having an ethylene oxide-based skeleton described in JP1983-049860B (JP-S58-049860B), JP1981-017654B (JP-S56-017654B), JP1987-039417B (JP-S62-039417B), and JP1987-039418B (JP-S62-039418B) are also suitable. In addition, it is also preferable to use the compound having ethylenically unsaturated bond groups, which has an amino structure or a sulfide structure in a molecule, described in JP1988-277653A (JP-S63-277653A), JP1988-260909A (JP-S63-260909A), and JP1989-105238A (JP-H01-105238A). Examples of a commercially available product thereof include urethane oligomers UAS-10 and UAB-140 (manufactured by Sanyo-kokusaku Pulp Co., Ltd.), UA-7200 (manufactured by Shin-Nakamura Chemical Co., Ltd.), DPHA-40H (manufactured by Nippon Kayaku Co., Ltd.), and UA-306H, UA-306T, UA-3061, AH-600, T-600, and AI-600 (manufactured by Kyoeisha Chemical Co., Ltd.).

The content of the compound having ethylenically unsaturated bond groups is preferably 0.1% to 50% by mass with respect to the total solid content of the coloring composition. The lower limit is more preferably 0.5% by mass or more, and still more preferably 1% by mass or more. The upper limit is more preferably 45% by mass or less, and still more preferably 40% by mass or less. The compounds having ethylenically unsaturated bond groups may be used singly or in combination of two or more kinds thereof. In a case where the compounds having ethylenically unsaturated bond groups are used in combination of two or more kinds thereof, the total amount thereof is preferably within the range.

Furthermore, in a case where the coloring composition includes a compound having ethylenically unsaturated bond groups, the content of the compound including 3 or more ethylenically unsaturated bond groups in the compounds having ethylenically unsaturated bond groups is preferably 60% by mass or more, more preferably 75% by mass or more, and still more preferably 90% by mass or more. According to this aspect, it is possible to form a cured film having more excellent light fastness.

In addition, the content of the compound including 3 or more ethylenically unsaturated bond groups and an alkyleneoxy group in the compounds having ethylenically unsaturated bond groups is preferably 60% by mass or more, more preferably 75% by mass or more, and still more preferably 90% by mass or more. According to this aspect, it is possible to impart appropriate flexibility onto a cured film, and it is thus possible to suppress pattern damages, peeling, or the like during development, and further increase the adhesiveness or film residual rates after development.

(Compound Having Epoxy Group)

The compound having an epoxy group (hereinafter also referred to as an epoxy compound) is preferably a compound having 1 to 100 epoxy groups per molecule. The lower limit of the number of the epoxy groups is more preferably 2 or more. The upper limit of the number of the epoxy groups can be set to, for example, 10 or less or 5 or less.

The epoxy equivalent (=the molecular weight of the epoxy compound/the number of epoxy groups) of the epoxy compound is preferably 500 g/eq or less, more preferably 100 to 400 g/eq, and still more preferably 100 to 300 g/eq.

The epoxy compound may be either a low-molecular-weight compound (for example, a molecular weight of less than 1,000) or a high-molecular-weight compound (macromolecule) (for example, a molecular weight of 1,000 or more, and in a case of a polymer, a weight-average molecular weight of 1,000 or more). The weight-average molecular weight of the epoxy compound is preferably 200 to 100,000, and more preferably 500 to 50,000. The upper limit of the weight-average molecular weight is preferably 10,000 or less, more preferably 5,000 or less, and still more preferably 3,000 or less.

As the epoxy compound, the compounds described in paragraph Nos. 0034 to 0036 of JP2013-011869A, paragraph Nos. 0147 to 0156 of JP2014-043556A, or paragraph Nos. 0085 to 0092 of JP2014-089408A, the contents of the publications are incorporated herein by reference, can also be used.

In a case where the coloring composition of the embodiment of the present invention contains an epoxy compound, the content of the epoxy compound is preferably 0.1% to 40% by mass with respect to the total solid content of the coloring composition. The lower limit is, for example, more preferably 0.5% by mass or more, and still more preferably 1% by mass or more. The upper limit is more preferably for example, more preferably 30% by mass or less, and still more preferably 20% by mass or less. The epoxy compounds may be used singly or in combination of two or more kinds thereof. In a case where the epoxy compounds are used in combination of two or more kinds thereof, the total amount thereof is preferably within the range.

The coloring composition of the embodiment of the present invention may not substantially contain an epoxy compound. The expression, not substantially containing an epoxy compound, means that the content of the epoxy compound is preferably 0.05% by mass or less, and more preferably 0.01% by mass or less, with respect to the total solid content of the coloring composition and still more preferably, the epoxy compound is not contained.

<<Photopolymerization Initiator>>

In a case where the coloring composition of the embodiment of the present invention contains a polymerizable compound as the curable compound, it is preferable that it preferably contains a photopolymerization initiator. The photopolymerization initiator is not particularly limited as long as it can initiate the polymerization of a polymerizable compound, and can be appropriately selected from known photopolymerization initiators. For example, the photopolymerization initiator is preferably a compound that is photosensitive to rays from an ultraviolet region to a visible region. Further, it may be a compound that causes a certain action with a photoexcited sensitizer to generate active radicals.

Examples of the photopolymerization initiator include halogenated hydrocarbon derivatives (for example, a compound having a triazine skeleton and a compound having an oxadiazole skeleton), an acylphosphine compound, hexaaryl biimidazole, an oxime compound, an organic peroxide, a thio compound, a ketone compound, an aromatic onium salt, an α-hydroxyketone compound, and an α-aminoketone compound. Moreover, from the viewpoint of the exposure sensitivity, in the photopolymerization initiator, a trihalomethyl triazine compound, a benzyl dimethyl ketal compound, an α-hydroxyketone compound, an α-aminoketone compound, an acylphosphine compound, a phosphine oxide compound, a metallocene compound, an oxime compound, a triarylimidazole dimer, an onium compound, a benzothiazole compound, a benzophenone compound, an aminoacetophenoen compound, a cyclopentadiene-benzene-iron complex, a halomethyl oxadiazole compound, and a 3-aryl-substituted coumarin compound are preferable, a compound selected from an oxime compound, the α-hydroxyketone compound, the α-aminoketone compound, and the acylphosphine compound is more preferable, and the oxime compound is still more preferable. With regard to the photopolymerization initiator, reference can be made to the description in paragraph Nos. 0065 to 0111 of JP2014-130173A, the contents of which are incorporated herein by reference.

Examples of a commercially available product of the α-hydroxyketone compound include IRGACURE-184, DAROCUR-1173, IRGACURE-500, IRGACURE-2959, and IRGACURE-127 (all manufactured by BASF). Examples of a commercially available product of the α-aminoketone compound include IRGACURE-907, IRGACURE-369, IRGACURE-379, and IRGACURE-379EG (all manufactured by BASF). Examples of a commercially available product of the acylphosphine compound include IRGACURE-819 and DAROCUR-TPO (both manufactured by BASF).

As an example of the oxime compound, the compounds described in JP2001-233842A, the compounds described in JP2000-080068A, or the compounds described in JP2006-342166A can be used. Specific examples of the oxime compound include 3-benzoyloxyiminobutan-2-one, 3-acetoxyiminobutan-2-one, 3-propionyloxyiminobutan-2-one, 2-acetoxyiminopentan-3-one, 2-acetoxyimino-1-phenylpropan-1-one, 2-benzoyloxyimino-1-phenylpropan-1-one, 3-(4-toluenesulfonyloxy)iminobutan-2-one, and 2-ethoxycarbonyloxyimino-1-phenylpropan-1-one.

As the oxime compound, the compounds described in J. C. S. Perkin II (1979), pp. 1653 to 1660, J. C. S. Perkin II (1979), pp. 156 to 162, Journal of Photopolymer Science and Technology (1995), pp. 202 to 232, each of the publications of JP2000-066385A, JP2000-080068A, JP2004-534797A, and JP2006-342166A, or the like can also be used. As a commercially available product of the oxime compound, IRGACURE-OXE01, IRGACURE-OXE02, IRGACURE-OXE03, and IRGACURE-OXE04 (all manufactured by BASF) are also suitably used. In addition, TRONLY TR-PBG-304, TRONLY TR-PBG-309, and TRONLY TR-PBG-305 (manufactured by CHANGZHOU TRONLY NEW ELECTRONIC MATERIALS CO., LTD.), or ADEKA ARKLS NCI-930 and ADEKA OPTOMER N-1919 (a photopolymerization initiator 2 described in JP2012-014052A) (all manufactured by ADEKA Corporation) can also be used.

Furthermore, as oxime compounds other than the above-described oxime compounds, the compound described in JP2009-519904A in which oxime is linked to an N-position of carbazole ring, the compound described in U.S. Pat. No. 7,626,957B in which a hetero-substituent is introduced into a benzophenone moiety, the compounds described in JP2010-015025A and US2009/0292039A in which a nitro group is introduced into a coloring agent moiety, the ketoxime compound described in WO2009/131189A, the compound described in U.S. Pat. No. 7,556,910B, which contains a triazine skeleton and an oxime skeleton in the same molecule, the compound described in JP2009-221114A, which has maximum absorption at 405 nm and has excellent sensitivity to a light source of g-rays, and the like, may be used. Preferably, reference can be made to the descriptions in, for example, paragraph Nos. 0274 to 0306 of JP2013-029760A, the contents of which are incorporated herein by reference.

In the present invention, an oxime compound having a fluorene ring can also be used as the photopolymerization initiator. Specific examples of the oxime compound having a fluorene ring include the compounds described in JP2014-137466A, the contents of which are incorporated herein by reference.

In the present invention, an oxime compound having a benzofuran skeleton can also be used as the photopolymerization initiator. Specific examples thereof include compounds OE-01 to OE-75 described in WO2015/036910A.

In the present invention, an oxime compound having a fluorine atom can also be used as the photopolymerization initiator. Specific examples of the oxime compound having a fluorine atom include the compounds described in JP2010-262028A, the compounds 24, and 36 to 40 described in JP2014-500852A, and the compounds (C-3) described in JP2013-164471A, the contents of which are incorporated herein by reference.

In the present invention, an oxime compound having a nitro group can be used as the photopolymerization initiator. It is also preferable that the oxime compound having a nitro group is a dimer. Specific examples of the oxime compound having a nitro group include the compounds described in paragraph Nos. 0031 to 0047 of JP2013-114249A, the compounds described in paragraph Nos. 0008 to 0012 and 0070 to 0079 of JP2014-137466A, and the compounds described in paragraph Nos. 0007 to 0025 of JP4223071B, and ADEKA ARKLS NCI-831 (manufactured by ADEKA Corporation).

Specific examples of the oxime compound that is preferably used in the present invention are shown below, but the present invention is not limited thereto.

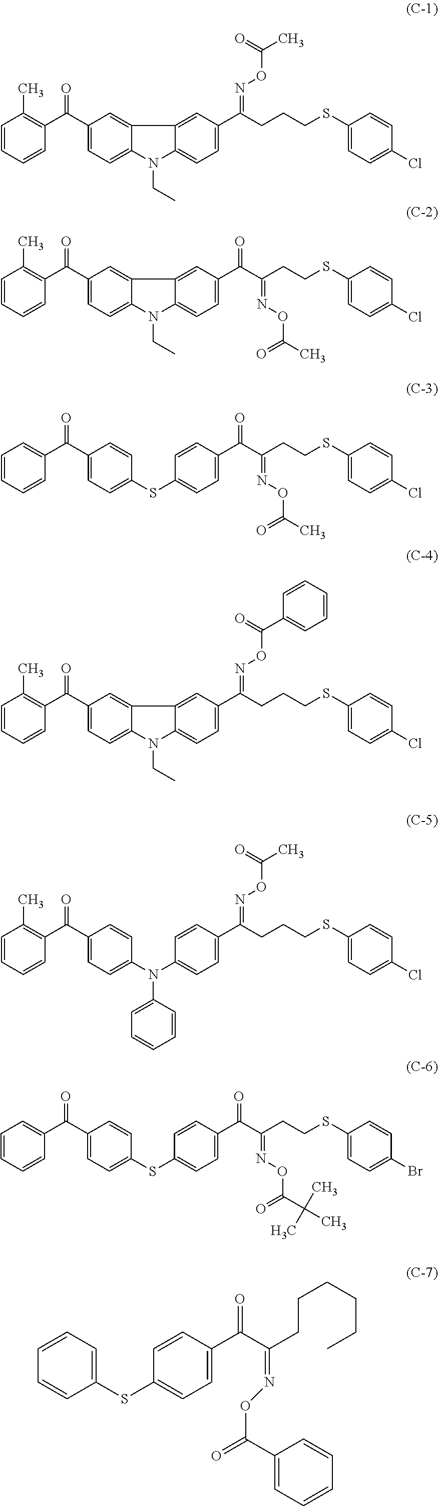

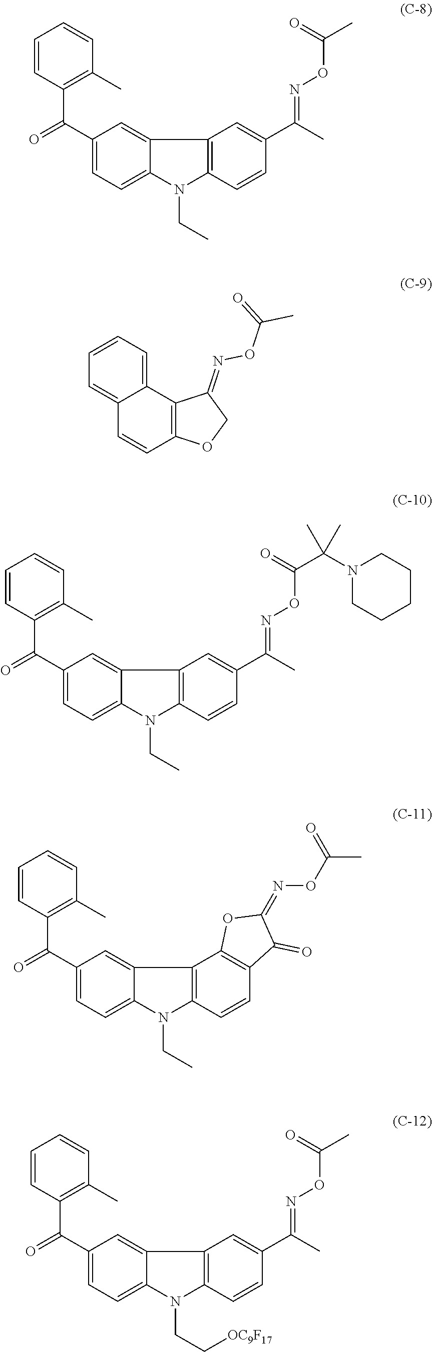

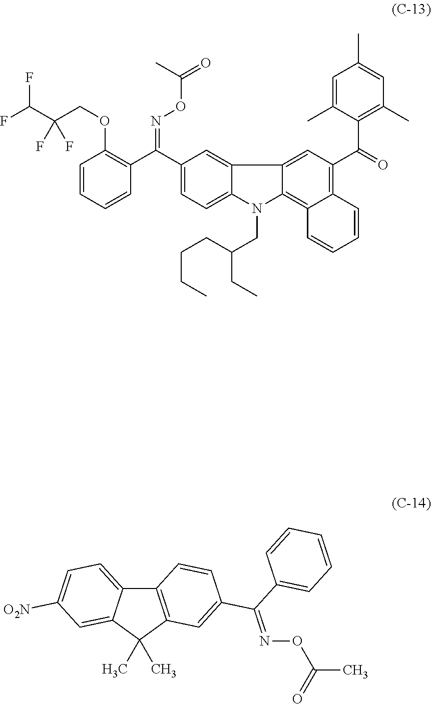 [SMILES: CCCCC(CC)Cn1c2ccc(/C(=N\OC(C)=O)c3ccccc3OCC(F)(F)C(F)F)cc2c2cc(C(=O)c3c(C)cc(C)cc3C)c3ccccc3c21 ; CC(=O)O/N=C(\c1ccccc1)c1ccc2c(c1)C(C)(C)c1cc([N+](=O)[O-])ccc1-2]

As the oxime compound, the compound having a maximum absorption wavelength in a wavelength range of 350 nm to 500 nm is preferable, the compound having a maximum absorption wavelength in a wavelength range of 360 nm to 480 nm is more preferable. The oxime compound is particularly preferably a compound showing a high absorbance at 365 nm and 405 nm.

From the viewpoint of sensitivity, the molar light absorption coefficient at 365 nm or 405 nm of the oxime compound is preferably 1,000 to 300,000, more preferably 2,000 to 300,000, and particularly preferably 5,000 to 200,000. The molar light absorption coefficient of the compound can be measured using a known method, but specifically, it is preferably measured, for example, by means of an ultraviolet and visible light spectrophotometer (Cary-5 spectrophotometer manufactured by Varian) at a concentration of 0.01 g/L using an ethyl acetate solvent.

The content of the photopolymerization initiator is preferably 0.1% to 50% by mass, more preferably 0.5% to 30% by mass, and still more preferably 1% to 20% by mass, with respect to the total solid content of the coloring composition. In a case where the content of the photopolymerization initiator is within the range, good sensitivity and good pattern forming properties are obtained. The coloring composition of the embodiment of the present invention may include only one kind or two or more kinds of the photopolymerization initiators. In a case where two or more kinds of the photopolymerization initiators are included, the total amount thereof is preferably within the range.

<<Solvent>>

The coloring composition of the embodiment of the present invention preferably contains a solvent. The solvent is preferably an organic solvent. The solvent is not particularly limited as long as it satisfies the solubility of the respective components or the coatability of the coloring composition.

Examples of the organic solvent include the following organic solvents. Examples of esters include ethyl acetate, n-butyl acetate, isobutyl acetate, cyclohexyl acetate, amyl formate, isoamyl acetate, butyl propionate, isopropyl butyrate, ethyl butyrate, butyl butyrate, methyl lactate, ethyl lactate, alkyl alkyloxyacetate esters (for example, methyl alkyloxyacetate, ethyl alkyloxyacetate, and butyl alkyloxyacetate (for example, methyl methoxyacetate, ethyl methoxyacetate, butyl methoxyacetate, methyl ethoxyacetate, and ethyl ethoxyacetate)), alkyl 3-alkyloxypropionate esters (for example, methyl 3-alkyloxypropionate and ethyl 3-alkyloxypropionate (for example, methyl 3-methoxypropionate, ethyl 3-methoxypropionate, methyl 3-ethoxypropionate, and ethyl 3-ethoxypropionate)), alkyl 2-alkyloxypropionate esters (for example, methyl 2-alkyloxypropionate, ethyl 2-alkyloxypropionate, and propyl 2-alkyloxypropionate (for example, methyl 2-methoxypropionate, ethyl 2-methoxypropionate, propyl 2-methoxypropionate, methyl 2-ethoxypropionate, and ethyl 2-ethoxypropionate)), methyl 2-alkyloxy-2-methyl propionate and ethyl 2-alkyloxy-2-methyl propionate (for example, methyl 2-methoxy-2-methyl propionate and ethyl 2-ethoxy-2-methyl propionate), methyl pyruvate, ethyl pyruvate, propyl pyruvate, methyl acetoacetate, ethyl acetoacetate, methyl 2-oxobutanoate, and ethyl 2-oxobutanoate. Examples of ethers include diethylene glycol dimethyl ether, tetrahydrofuran, ethylene glycol monomethyl ether, ethylene glycol monoethyl ether, methyl cellosolve acetate, ethyl cellosolve acetate, diethylene glycol monomethyl ether, diethylene glycol monoethyl ether, diethylene glycol monobutyl ether, propylene glycol monomethyl ether, propylene glycol monomethyl ether acetate, propylene glycol monoethyl ether acetate, and propylene glycol monopropyl ether acetate. Examples of the ketones include methyl ethyl ketone, cyclohexanone, cyclopentanone, 2-heptanone, and 3-heptanone. Suitable examples of the aromatic hydrocarbons include toluene and xylene. However, it is preferable in some cases to reduce aromatic hydrocarbons (benzene, toluene, xylene, ethylbenzene, and the like) (for example, the amount can be set to 50 parts per million (ppm) by mass or less, 10 ppm by mass or less, or 1 ppm by mass or less with respect to the total amount of the organic solvent) as a solvent for a reason such as an environmental aspect.

The organic solvents may be used singly or in combination of two or more kinds thereof. In a case where the organic solvents are used in combination of two or more kinds thereof, the solvent is particularly preferably a mixed solution formed of two or more kinds selected from methyl 3-ethoxypropionate, ethyl 3-ethoxypropionate, ethyl cellosolve acetate, ethyl lactate, diethylene glycol dimethyl ether, butyl acetate, methyl 3-methoxypropionate, 2-heptanone, cyclohexanone, ethyl carbitol acetate, butyl carbitol acetate, propylene glycol methyl ether, and propylene glycol monomethyl ether acetate.

In the present invention, the organic solvent E preferably has a content of peroxides of 0.8 mmol/L or less, and more preferably, it does not substantially include peroxides. Further, it is preferable to use an organic solvent having a small metal content, and for example, the metal content of the organic solvent is preferably 10 parts per billion (ppb) by mass or less. The metal content of the organic solvent is at a level of parts per trillion (ppt) by mass, as desired, and such a high-purity solvent is provided by, for example, Toyo Kasei Kogyo Co., Ltd. (The Chemical Daily, Nov. 13, 2015).

The content of the solvent is preferably an amount such that the total solid content of the coloring composition is 5% to 80% by mass. The lower limit is preferably 10% by mass or more. The upper limit is preferably 60% by mass or less, more preferably 50% by mass or less, and still more preferably 40% by mass or less.

<<Curing Accelerator>>

The coloring composition of the embodiment of the present invention may include a curing accelerator for the purpose of improving the hardness of a pattern or lowering a curing temperature. Examples of the curing accelerator include a thiol compound.

Examples of the thiol compound include a polyfunctional thiol compound having two or more mercapto groups in a molecule thereof. The polyfunctional thiol compound may also be added for the purpose of alleviating problems in stability, smell, developability, adhesiveness, or the like. The polyfunctional thiol compound is preferably a secondary alkanethiol, and more preferably a compound having a structure represented by Formula (T1).

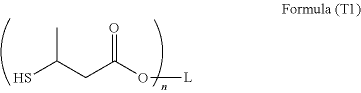

In Formula (T1), n represents an integer of 2 to 4, and L represents a divalent to tetravalent linking group.

In Formula (T1), it is preferable that L is an aliphatic group having 2 to 12 carbon atoms. In Formula (T1), it is more preferable that n is 2 and L is an alkylene group having 2 to 12 carbon atoms. Specific examples of the polyfunctional thiol compounds include compounds represented by Structural Formulae (T2) to (T4), and the compound represented by Formula (T2) is preferable. These thiol compounds can be used singly or in combination of two or more kinds thereof.

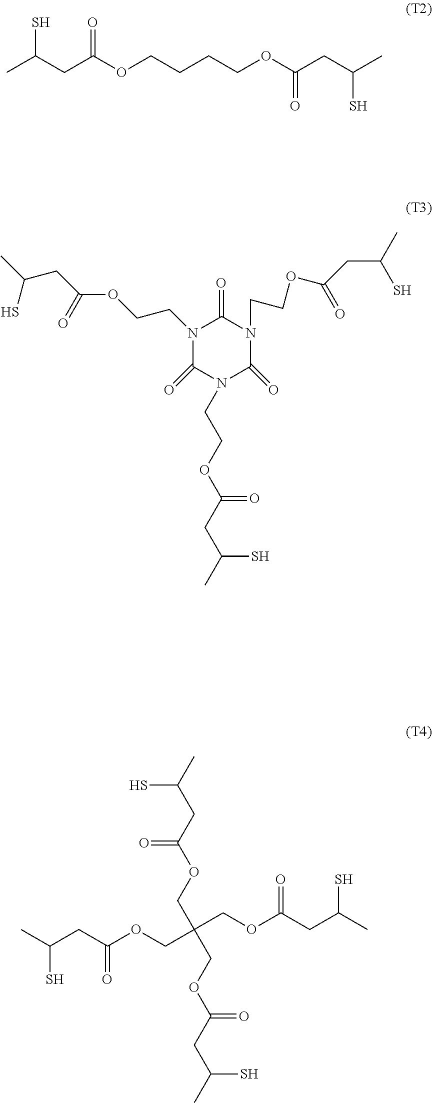

Moreover, as the curing accelerator, a methylol-based compound (for example, the compounds exemplified as a crosslinking agent in paragraph No. 0246 of JP2015-034963A), amines, phosphonium salts, amidine salts, amide compounds (each of which are the curing agents described in, for example, paragraph No. 0186 of JP2013-041165A), base generators (for example, the ionic compounds described in JP2014-055114A), isocyanate compounds (for example, the compounds described in paragraph No. 0071 of JP2012-150180A), alkoxysilane compounds (for example, the alkoxysilane compounds having epoxy groups, described in JP2011-253054A), onium salt compounds (for example, the compounds exemplified as an acid generator in paragraph No. 0216 of JP2015-034963A, and the compounds described in JP2009-180949A), or the like can be used.

In a case where the coloring composition of the embodiment of the present invention contains the curing accelerator, the content of the curing accelerator is preferably 0.3% to 8.9% by mass, and more preferably 0.8% to 6.4% by mass, with respect to the total solid content of the coloring composition.

<<Pigment Derivative>>

The coloring composition of the embodiment of the present invention preferably contains a pigment derivative. Examples of the pigment derivative include a compound having a structure in which a part of a chromophore is substituted with an acid group, a basic group, or a phthalimidemethyl group.

Examples of a chromophore constituting the pigment derivative include a quinoline-based skeleton, a benzimidazolone-based skeleton, a diketopyrrolopyrrole-based skeleton, an azo-based skeleton, a phthalocyanine-based skeleton, an anthraquinone-based skeleton, a quinacridone-based skeleton, a dioxazine-based skeleton, a perinone-based skeleton, a perylene-based skeleton, a thioindigo-based skeleton, an isoindoline-based skeleton, an isoindolinone-based skeleton, a quinophthalone-based skeleton, a threne-based skeleton, and a metal complex-based skeleton, the quinoline-based skeleton, the benzimidazolone-based skeleton, the diketopyrrolopyrrole-based skeleton, the azo-based skeleton, the quinophthalone-based skeleton, the isoindoline-based skeleton, and the phthalocyanine-based skeleton are preferable, and the azo-based skeleton and the benzimidazolone-based skeleton are more preferable. As the acid group contained in the pigment derivative, a sulfo group or a carboxyl group is preferable, and the sulfo group is more preferable. As the basic group contained in the pigment derivative, an amino group is preferable, and a tertiary amino group is more preferable. With regard to specific examples of the pigment derivative, reference can be made to the description in paragraphs 0162 to 0183 of JP2011-252065A, the contents of which are incorporated herein by reference.

In a case where the coloring composition of the embodiment of the present invention contains a pigment derivative, the content of the pigment derivative is preferably 1 to 30 parts by mass, and more preferably 3 to 20 parts by mass, with respect to 100 parts by mass of the pigment. The pigment derivative may be used singly or in combination of two or more kinds thereof.

<<Surfactant>>

The coloring composition of the embodiment of the present invention preferably contains a surfactant. As the surfactant, various surfactants such as a fluorine-based surfactant, a nonionic surfactant, a cationic surfactant, an anionic surfactant, and a silicone-based surfactant can be used, and the fluorine-based surfactant is preferable for a reason that coatability can be further improved.

By incorporating the fluorine-based surfactant into the coloring composition of the embodiment of the present invention, liquid characteristics in a case of preparation of a coating liquid are further improved, and thus, the evenness of coating thickness can be further improved. That is, in a case where a film is formed using to which a coloring composition containing the fluorine-based surfactant has been applied, the interface tension between a surface to be coated and the coating liquid is reduced to improve wettability with respect to the surface to be coated, and enhance coatability with respect to the surface to be coated. Therefore, formation of a film with a uniform thickness which exhibits little coating unevenness can be more suitably performed.

The fluorine content in the fluorine-based surfactant is preferably 3% to 40% by mass, more preferably 5% to 30% by mass, and particularly preferably 7% to 25% by mass. The fluorine-based surfactant in which the fluorine content falls within this range is effective in terms of the evenness of the thickness of the coating film or liquid saving properties, and the solubility of the surfactant in the coloring composition is also good.

Examples of the fluorine-based surfactant include MEGAFACE F171, F172, F173, F176, F177, F141, F142, F143, F144, R30, F437, F475, F479, F482, F554, and F780 (all manufactured by DIC Corporation), FLUORAD FC430, FC431, and FC171 (all manufactured by Sumitomo 3M), SURFLON S-382, SC-101, SC-103, SC-104, SC-105, SC-1068, SC-381, SC-383, and S-393, and KH-40 (all manufactured by Asahi Glass Co., Ltd.), and PF636, PF656, PF6320, PF6520, and PF7002 (all manufactured by OMNOVA). Further, as the fluorine-based surfactant, the compounds described in paragraph Nos. 0015 to 0158 of JP2015-117327A, and the compounds described in paragraph Nos. 0117 to 0132 of JP2011-132503A can be used. As the fluorine-based surfactant, a block polymer can also be used, and specific examples thereof include the compounds described in JP2011-089090A.

As the fluorine-based surfactant, an acrylic compound in which by application of heat to a molecular structure containing a functional group having a fluorine atom, in which the functional group containing a fluorine atom is cut to volatilize a fluorine atom, can also be suitably used. Examples of the fluorine-based surfactant include MEGAFACE DS series (manufactured by DIC Corporation, The Chemical Daily, Feb. 22, 2016, Nikkei Business Daily, Feb. 23, 2016), for example, MEGAFACE DS-21, which may also be used.

As the fluorine-based surfactant, a fluorine-containing polymer compound including a repeating unit derived from a (meth)acrylate compound having a fluorine atom and a repeating unit derived from a (meth)acrylate compound having 2 or more (preferably 5 or more) alkyleneoxy groups (preferably ethyleneoxy groups or propyleneoxy groups) can also be preferably used, and the following compounds are also exemplified as a fluorine-based surfactant for use in the present invention. In the following in the formula, % representing the ratio of the repeating unit is % by mole.

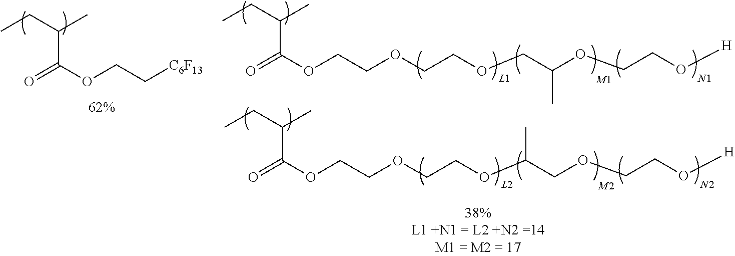

The weight-average molecular weight of the compounds is preferably 3,000 to 50,000, and is, for example, 14,000.

A fluorine-containing polymer having an ethylenically unsaturated bonding group in a side chain can also be used as the fluorine-based surfactant. Specific examples thereof include the compounds described in paragraph Nos. 0050 to 0090 and paragraph Nos. 0289 to 0295 of JP2010-164965A. Examples of commercially available products thereof include MEGAFACE RS-101, RS-102, RS-718-K, and RS-72-K, all of which are manufactured by DIC Corporation.

Examples of the nonionic surfactant include glycerol, trimethylolpropane, trimethylolethane, and ethoxylate and propoxylate thereof (for example, glycerol propoxylate and glycerol ethoxylate), polyoxyethylene lauryl ether, polyoxyethylene stearyl ether, polyoxyethylene oleyl ether, polyoxyethylene octyl phenyl ether, polyoxyethylene nonyl phenyl ether, polyethylene glycol dilaurate, polyethylene glycol distearate, sorbitan fatty acid esters, PLURONIC L10, L31, L61, L62, 10R5, 17R2, and 25R2 (manufactured by BASF), TETRONIC 304, 701, 704, 901, 904, and 150R1 (manufactured by BASF), SOLSEPERSE 20000 (manufactured by Lubrizol Japan Ltd.), NCW-101, NCW-1001, and NCW-1002 (manufactured by Wako Pure Chemical Industries, Ltd.), PIONIN D-6112, D-6112-W, and D-6315 (manufactured by Takemoto Oil & Fat Co., Ltd.), and OLFINE E1010, and SURFYNOL 104, 400, and 440 (manufactured by Nissin chemical industry Co., Ltd.).

Specific examples of the cationic surfactant include an organosiloxane polymer KP341 (manufactured by Shin-Etsu Chemical Co., Ltd.), a (meth)acrylic acid-based (co)polymer POLYFLOW No. 75, No. 90, and No. 95 (manufactured by KYOEISHA CHEMICAL CO., LTD.), and W001 (manufactured by Yusho Co., Ltd.).

Examples of the anionic surfactant include W004, W005, and W017 (manufactured by Yusho Co., Ltd.), and BL (manufactured by Sanyo Chemical Industries, Ltd.).

Examples of the silicone-based surfactant include TORAY SILICONE DC3PA, TORAY SILICONE SH7PA, TORAY SILICONE DC11PA, TORAY SILICONE SH21PA, TORAY SILICONE SH28PA, TORAY SILICONE SH29PA, TORAY SILICONE SH30PA, and TORAY SILICONE SH8400 (all manufactured by Dow Corning Toray Co., Ltd.), TSF-4440, TSF-4300, TSF-4445, TSF-4460, and TSF-4452 (all manufactured by Momentive Performance Materials Co., Ltd.), KP341, KF6001, and KF6002 (all manufactured by Shin-Etsu Chemical Co., Ltd.), and BYK307, BYK323, and BYK330 (all manufactured by BYK Chemie).

The content of the surfactant is preferably 0.001% to 2.0% by mass, and more preferably 0.005% to 1.0% by mass, with respect to the total solid content of the coloring composition. The surfactant may be used alone or in combination of two or more kinds thereof. In a case where two or more kinds of the surfactants are included, the total amount thereof is preferably within the range.

<<Silane Coupling Agent>>

The coloring composition of the embodiment of the present invention can contain a silane coupling agent. In the present invention, the silane coupling agent means a silane compound having a hydrolyzable group and another functional group. Further, the hydrolyzable group refers to a substituent that can be directly linked to a silicon atom to generate a siloxane bond by a hydrolysis reaction and/or a condensation reaction. Examples of the hydrolyzable group include a halogen atom, an alkoxy group, and an acyloxy group.

The silane coupling agent is preferably a silane compound having at least one selected from a vinyl group, an epoxy group, a styryl group, a methacryl group, an amino group, an isocyanurate group, a ureido group, a mercapto group, a sulfide group, and an isocyanate group, or an alkoxy group. Specific examples of the silane coupling agent include N-β-aminoethyl-γ-aminopropyl methyldimethoxysilane (KBM-602, manufactured by Shin-Etsu Chemical Co., Ltd.), N-β-aminoethyl-γ-aminopropyl trimethoxysilane (KBM-603, manufactured by Shin-Etsu Chemical Co., Ltd.), N-β-aminoethyl-γ-aminopropyl triethoxysilane (KBE-602, manufactured by Shin-Etsu Chemical Co., Ltd.), γ-aminopropyl trimethoxysilane (KBM-903, manufactured by Shin-Etsu Chemical Co., Ltd.), γ-aminopropyl triethoxysilane (KBE-903, manufactured by Shin-Etsu Chemical Co., Ltd.), 3-methacryloxypropyl trimethoxysilane (KBM-503, manufactured by Shin-Etsu Chemical Co., Ltd.), and 3-glycidoxypropyl trimethoxysilane (KBM-403, manufactured by Shin-Etsu Chemical Co., Ltd.). With regard to details of the silane coupling agent, reference can be made to the description in paragraph Nos. 0155 to 0158 of JP2013-254047A, the contents of which are incorporated herein by reference.

In a case where the coloring composition of the embodiment of the present invention contains a silane coupling agent, the content of the silane coupling agent is preferably 0.001% to 20% by mass, more preferably 0.01% to 10% by mass, and particularly preferably 0.1% to 5% by mass, with respect to the total solid content of the coloring composition. The coloring composition of the embodiment of the present invention may include one kind or two or more kinds of the silane coupling agents. In a case where the coloring composition includes two or more kinds of the silane coupling agent, the total amount thereof is preferably within the range.

<<Polymerization Inhibitor>>

The coloring composition of the embodiment of the present invention can contain a polymerization inhibitor. Examples of the polymerization inhibitor include hydroquinone, p-methoxyphenol, di-t-butyl-p-cresol, pyrogallol, t-butyl catechol, benzoquinone, 4,4′-thiobis(3-methyl-6-t-butylphenol), 2,2′-methylenebis(4-methyl-6-t-butylphenol), and an N-nitrosophenylhydroxylamine salt (an ammonium salt, a cerous salt, or the like).

In a case where the coloring composition of the embodiment of the present invention contains a polymerization inhibitor, the content of the polymerization inhibitor is preferably 0.01% to 5% by mass with respect to the total solid content of the coloring composition. The coloring composition of the embodiment of the present invention may include one kind or two or more kinds of the polymerization inhibitor. In a case where the coloring composition includes two or more kinds of the polymerization inhibitor, the total amount thereof is preferably within the range.

<<Ultraviolet Absorber>>

The coloring composition of the embodiment of the present invention can contain an ultraviolet absorber. As the ultraviolet absorber, a conjugated diene compound, an aminobutadiene compound, a methyldiebenzoyl compound, a coumarin compound, a salicylate compound, a benzophenone compound, a benzotriazole compound, an acrylonitrile compound, a hydroxyphenyltriazine compound, or the like can be used. With regard to details thereof, reference can be made to the description in paragraph Nos. 0052 to 0072 of JP2012-208374A and paragraph Nos. 0317 to 0334 of JP2013-068814A, the contents of which are incorporated herein by reference. Examples of commercially available products of the ultraviolet absorber include UV-503 (manufactured by Daito Chemical Co., Ltd.). In addition, as the benzotriazole compound, MYUA series manufactured by Miyoshi Oil & Fat Co., Ltd. (The Chemical Daily, Feb. 1, 2016) may be used.

In a case where the coloring composition of the embodiment of the present invention contains an ultraviolet absorber, the content of the ultraviolet absorber is preferably 0.1% to 10% by mass, more preferably 0.1% to 5% by mass, and particularly preferably 0.1% to 3% by mass, with respect to the total solid content of the coloring composition. Further, only one kind or two or more kinds of the ultraviolet absorbers may be used. In a case where two or more kinds of the ultraviolet absorbers are included, the total amount thereof is preferably within the range.

<<Other Additives>>

Various additives such as a filler, an adhesion promoter, an antioxidant, and an aggregation inhibitor can be blended into the coloring composition of the embodiment of the present invention, as desired. Examples of these additives include the additives described in paragraph Nos. 0155 and 0156 of JP2004-295116A, the contents of which are incorporated herein by reference. Further, as the antioxidant, for example, a phenol compound, a phosphorus-based compound (for example, the compounds described in paragraph No. 0042 of JP2011-090147A), a thioether compound, or the like can be used. Examples of a commercially available product thereof include ADEKA STAB series (AO-20, AO-30, AO-40, AO-50, AO-50F, AO-60, AO-60G, AO-80, AO-330, and the like), all of which are manufactured by ADEKA. Only one kind or two or more kinds of the antioxidants may be used as a mixture of two or more kinds thereof. The coloring composition of the embodiment of the present invention can contain the sensitizers or the light stabilizers described in paragraph No. 0078 of JP2004-295116A, or the thermal polymerization inhibitors described in paragraph No. 0081 of the same publication.

There are some cases where a metal element is included in the coloring composition according to raw materials and the like, but from the viewpoint of suppression of generation of defects, or the like, the content of Group 2 elements (calcium, magnesium, and the like) in the coloring composition is preferably 50 parts per million (ppm) by mass or less, and more preferably 0.01 to 10 ppm by mass. Further, the total amount of the inorganic metal salts in the coloring composition is preferably 100 ppm by mass or less, and more preferably 0.5 to 50 ppm by mass.

The moisture content in the coloring composition of the embodiment of the present invention is usually 3% by mass or less, preferably 0.01% to 1.5% by mass, and more preferably in the range of 0.1% to 1.0% by mass. The moisture content can be measured by a Karl Fischer method.

The coloring composition of the embodiment of the present invention can be used after its viscosity is adjusted for the purposes of adjusting the state of a film surface (flatness or the like), adjusting a film thickness, or the like. The value of the viscosity can be appropriately selected as desired, and is, for example, preferably 0.3 mPa·s to 50 mPa·s, and more preferably 0.5 mPa·s to 20 mPa·s at 25° C. As for a method for measuring the viscosity, the viscosity can be measured, for example, with a temperature being adjusted to 25° C., using a viscometer RE85L (rotor: 1°34′×R24, measurement range of 0.6 to 1,200 mPa·s) manufactured by Toki Sangyo Co., Ltd.

A storage container for the coloring composition of the embodiment of the present invention is not particularly limited, and a known storage container can be used. Further, as the storage container, it is also preferable to use a multilayer bottle having an inner wall constituted with six layers from six kinds of resins or a bottle having a 7-layer structure from 6 kinds of resins for the purpose of suppressing incorporation of impurities into raw materials or compositions. Examples of such a container include the containers described in JP2015-123351A.

The coloring composition of the embodiment of the present invention can be preferably used for the formation of colored pixels (preferably red pixels) in a color filter. The coloring composition of the embodiment of the present invention can be preferably used for a color filter in a solid-state imaging element such as a charge coupled device (CCD) and a complementary metal-oxide semiconductor (CMOS), an image display device, or the like.

In a case where the coloring composition of the embodiment of the present invention is used as a color filter in applications for a liquid crystal display device, the voltage holding ratio of a liquid crystal display element comprising a color filter is preferably 70% or more, and more preferably 90% or more. Known means for obtaining a high voltage holding ratio can be incorporated as appropriate, and examples of typical means include use of high-purity materials (for example, reduction in ionic impurities) and control of the amount of acidic functional groups in a composition. The voltage holding ratio can be measured by, for example, the methods described in paragraph 0243 of JP2011-008004A and paragraphs 0123 to 0129 of JP2012-224847A.

<Method for Preparing Coloring Composition>

The coloring composition of the embodiment of the present invention can be prepared by mixing the above-mentioned components. In the preparation of the coloring composition, all the components may be dissolved and/or dispersed at the same time in a solvent to prepare the coloring composition, or the respective components may be appropriately left in two or more solutions or dispersion liquids and mixed to prepare the coloring composition upon use (during coating), as desired.

Furthermore, in the preparation of the coloring composition, a process for dispersing the pigment is preferably included. In the process for dispersing the pigment, examples of a mechanical force that is used for dispersion of the pigment include compression, pressing, impact, shear, and cavitation. Specific examples of these processes include a beads mill, a sand mill, a roll mill, a ball mill, a paint shaker, a microfluidizer, a high-speed impeller, a sand grinder, a flow jet mixer, high-pressure wet atomization, and ultrasonic dispersion. Further, in the pulverization of the pigment in a sand mill (beads mill), it is preferable to perform a treatment under the condition for increasing a pulverization efficiency by using beads having small diameters; increasing the filling rate of the beads; or the like. Incidentally, it is preferable to remove coarse particles by filtration, centrifugation, or the like after the pulverization treatment. In addition, as the process and the dispersing machine for dispersing the pigment, the process and the dispersing machine described in “Dispersion Technology Comprehension, published by Johokiko Co., Ltd., Jul. 15, 2005”, “Actual comprehensive data collection on dispersion technology and industrial application centered on suspension (solid/liquid dispersion system), published by Publication Department, Management Development Center, Oct. 10, 1978”, and paragraph No. 0022 of JP2015-157893A can be suitably used. In addition, in the process for dispersing the pigment, a refining treatment of particles in a salt milling process may be performed. With regard to the materials, the equipment, the process conditions, and the like used in the salt milling process, reference can be made to, for example, the description in JP2015-194521A and JP2012-046629A.

It is preferable that in the preparation of the coloring composition, a composition formed by mixing the respective components is filtered through a filter for the purpose of removing foreign matters, reducing defects, or the like. As the filter, any filters that have been used in the related art for filtration use and the like may be used without particular limitation. Examples of the filter include filters formed of materials including, for example, a fluorine resin such as polytetrafluoroethylene (PTFE), a polyamide-based resin such as nylon (for example, nylon-6 and nylon-6,6), and a polyolefin resin (including a polyolefin resin having a high density and/or an ultrahigh molecular weight) such as polyethylene and polypropylene (PP). Among these materials, polypropylene (including a high-density polypropylene) and nylon are preferable.

The pore diameter of the filter is suitably approximately 0.01 to 7.0 μm, preferably approximately 0.01 to 3.0 μm, and more preferably approximately 0.05 to 0.5 μm.

In addition, a fibrous filter material is also preferably used as the filter. Examples of the fibrous filter material include a polypropylene fiber, a nylon fiber, and a glass fiber. Examples of a filter using the fibrous filter material include filter cartridges of SBP type series (SBP008 and the like), TPR type series (TPR002, TPR005, and the like), or SHPX type series (SHPX003 and the like), manufactured by Roki Techno Co., Ltd.

In a case of using a filter, different filters may be combined. Here, the filtration with each of the filters may be performed once or may be performed twice or more times.

For example, filters having different pore diameters within the above-mentioned range may be combined. With regard to the pore diameter of the filter herein, reference can be made to nominal values of filter manufacturers. A commercially available filter may be selected from, for example, various filters provided by Nihon Pall Corporation (DFA4201NXEY and the like), Toyo Roshi Kaisha., Ltd., Nihon Entegris K. K. (formerly Nippon Microlith Co., Ltd.), Kitz Micro Filter Corporation, and the like.

In addition, the filtration through the first filter may be performed with only a dispersion liquid, the other components may be mixed therewith, and then the filtration through the second filter may be performed. As the second filter, a filter formed of the same material as that of the first filter, or the like can be used.

<Cured Film>

The cured film of an embodiment of the present invention is a cured film obtained from the above-mentioned coloring composition of the embodiment of the present invention. The cured film of the embodiment of the present invention can be preferably used as a color filter.

The film thickness of the cured film can be appropriately adjusted depending on purposes. For example, the film thickness is preferably 20 μm or less, more preferably 10 μm or less, and still more preferably 5 μm or less. The lower limit of the film thickness is preferably 0.1 μm or more, more preferably 0.2 μm or more, and still more preferably 0.3 μm or more.

<Structure>

The structure of an embodiment of the present invention is a structure in which an oxygen-shielding film is formed on the above-mentioned cured film of the embodiment of the present invention. In the structure, the cured film of the embodiment of the present invention and the oxygen-shielding film may be adjacent to each other, and another layer may be interposed therebetween. The oxygen transmittance of the oxygen-shielding film is preferably 200 ml/m²·day·atm or less, more preferably 100 ml/m²·day·atm or less, and particularly preferably 50 ml/m²·day·atm or less. The lower limit is not particularly limited, and is preferably 0 ml/m²·day·atm. The oxygen transmittance of the oxygen-shielding film can be measured by, for example, the following manner. A Model 3600 manufactured by Orbisphere Laboratories Japan Ink Co., Ltd. is used as an oxygen electrode. Polyfluoroalkoxy (PFA) 2956A is used as an electrode diaphragm. Silicone grease (SH 111, manufactured by Dow Corning Toray Co., Ltd.) is thinly applied onto the electrode diaphragm, a thin film material to be measured is pasted thereon, and an oxygen concentration value is measured. Further, it is confirmed that a coating film of silicone grease does not affect the oxygen transmission rate. Next, the oxygen transmission rate (ml/m²·day·atm) with respect to the oxygen concentration value is converted. With regard to the oxygen-shielding film, reference can be made to, for example, the description in the paragraphs 0217 to 0221 in JP2011-248197A, the contents of which are incorporated herein by reference.

<Color Filter>

Next, the color filter of an embodiment of the present invention will be described.

The color filter of the embodiment of the present invention has the above-mentioned cured film of the embodiment of the present invention. In the color filter of the embodiment of the present invention, the film thickness of the cured film can be appropriately adjusted depending on the purposes. The film thickness is preferably 20 μm or less, more preferably 10 μm or less, and still more preferably 5 μm or less. The lower limit of the film thickness is preferably 0.1 μm or more, more preferably 0.2 μm or more, and still more preferably 0.3 μm or more. The color filter of the embodiment of the present invention can be used for a solid-state imaging element such as a charge coupled device (CCD) and a complementary metal-oxide semiconductor (CMOS), an image display device, or the like.

<Pattern Forming Method>

Next, a pattern forming method using the coloring composition of the embodiment of the present invention will be described. The pattern forming method includes a step of forming a coloring composition layer on a support using the coloring composition of the embodiment of the present invention, and a step of forming a pattern onto the coloring composition layer by photolithography or a dry etching method.

Pattern formation by the photolithography preferably includes a step of forming a coloring composition layer on a support using the coloring composition, a step of patternwise exposing the coloring composition layer, and a step of removing unexposed areas by development to form a pattern. A step of baking the coloring composition layer (pre-baking step) and a step of baking the developed pattern (post-baking step) may be provided, as desired. Further, pattern formation by a dry etching method preferably includes a step of forming a coloring composition layer on a support using the coloring composition, a step of curing the coloring composition layer to form a cured product layer, a step of forming a photoresist layer on the cured product layer, a step of performing exposure and development to pattern the photoresist layer, thereby obtaining a resist pattern, and a step of dry etching the cured product layer using the resist pattern as an etching mask to form a pattern. Hereinafter, the respective steps will be described.

<<Step of Forming Coloring Composition Layer>>

In the step of forming a coloring composition layer, the coloring composition layer is formed on a support, using the coloring composition.

The support is not particularly limited, and can be appropriately selected depending on applications. Examples of the support include a glass substrate, a substrate for a solid-state imaging element, on which a solid-state imaging element (light-receiving element) such as a CCD and a CMOS is provided, and a silicon substrate. Further, an undercoat layer may be provided on the support, as desired, so as to improve adhesion to a layer above the support, to prevent diffusion of materials, or to flatten a surface of the substrate.

As a method for applying the coloring composition onto the support, various coating methods such as slit coating, an ink jet method, spin coating, cast coating, roll coating, and a screen printing method can be used.

The coloring composition layer formed on the support may be dried (pre-baked). In a case of forming a pattern by a low-temperature process, pre-baking may not be performed. In a case of performing the pre-baking, the pre-baking temperature is preferably 150° C. or lower, more preferably 120° C. or lower, and still more preferably 110° C. or lower. The lower limit may be set to, for example, 50° C. or higher, or to 80° C. or higher. By setting the pre-baking temperature to 150° C. or lower, these characteristics can be more effectively maintained in a case of a configuration in which a photo-electric conversion film of an image sensor is formed of organic materials. The pre-baking time is preferably 10 seconds to 300 seconds, more preferably 40 to 250 seconds, and still more preferably 80 to 220 seconds. Drying can be performed using a hot plate, an oven, or the like.

(Case of Forming Pattern by Photolithographic Method)

<<Exposing Step>>

Next, the coloring composition layer formed on the support is patternwise exposed (exposing step). For example, the coloring composition layer can be subjected to patternwise exposure by performing exposure using an exposure device such as a stepper through a mask having a predetermined mask pattern. Thus, the exposed portion can be cured. As the radiation (light) which can be used during the exposure, ultraviolet rays such as g-rays and i-rays (particularly preferably i-rays) are preferably used. The irradiation dose (exposure dose) is, for example, preferably 0.03 to 2.5 J/cm², and more preferably 0.05 to 1.0 J/cm². The oxygen concentration during the exposure can be appropriately selected, and the exposure may also be performed, for example, in a low-oxygen atmosphere having an oxygen concentration of 19% by volume or less (for example, 15% by volume, 5% by volume, and substantially oxygen-free) or in a high-oxygen atmosphere having an oxygen concentration of more than 21% by volume (for example, 22% by volume, 30% by volume, and 50% by volume), in addition to an atmospheric air. Further, the exposure illuminance can be appropriately set, and can be usually selected from a range of 1,000 W/m² to 100,000 W/m² (for example, 5,000 W/m², 15,000 W/m², or 35,000 W/m²). Appropriate conditions of each of the oxygen concentration and the illuminance of exposure energy may be combined, and for example, a combination of the oxygen concentration of 10% by volume and the illuminance of 10,000 W/m², a combination of the oxygen concentration of 35% by volume and the illuminance of 20,000 W/m², or the like is available.

<<Developing Step>>

Next, the unexposed areas are removed by development to form a pattern. The removal of the unexposed areas by development can be carried out using a developer. Thus, the coloring composition layer of the unexposed areas in the exposing step is eluted into the developer, and as a result, only a photocured portion remains.

As the developer, an organic alkali developer causing no damage on the underlying solid-state imaging element, circuit, or the like is preferable.

The temperature of the developer is preferably for example, 20° C. to 30° C., and the development time is preferably 20 to 180 seconds. Further, in order to improve residue removing properties, a step of removing the developer by shaking per 60 seconds and supplying a fresh developer may be repeated multiple times.

As the developer, an aqueous alkaline solution obtained by diluting an alkali agent with pure water is preferably used. Examples of the alkali agent include organic alkaline compounds such as aqueous ammonia, ethylamine, diethylamine, dimethylethanolamine, diglycol amine, diethanolamine, hydroxyamine, ethylenediamine, tetramethylammonium hydroxide, tetraethylammonium hydroxide, tetrapropylammonium hydroxide, tetrabutylammonium hydroxide, ethyltrimethylammonium hydroxide, benzyltrimethylammonium hydroxide, dimethylbis(2-hydroxyethyl)ammonium hydroxide, choline, pyrrole, piperidine, and 1,8-diazabicyclo[5.4.0]-7-undecene, and inorganic alkaline compounds such as sodium hydroxide, potassium hydroxide, sodium carbonate, sodium hydrogen carbonate, sodium silicate, and sodium metasilicate. The concentration of the alkali agent in the aqueous alkaline solution is preferably 0.001% to 10% by mass, and more preferably 0.01% to 1% by mass. Moreover, the developer may further include a surfactant. Examples of the surfactant include the surfactants described as the above-mentioned coloring composition, and the surfactant is preferably a nonionic surfactant. The developer may be first produced as a concentrated liquid and then diluted to a concentration required upon from the viewpoints of transportation, storage, and the like. The dilution ratio is not particularly limited, and can be set to, for example, a range of 1.5 to 100 times. In addition, in a case where a developer including such an aqueous alkaline solution is used, it is preferable to perform washing (rinsing) with pure water after development.

After the development, a heating treatment (post-baking) can also be performed after carrying out drying. The post-baking is a heating treatment after development so as to complete the curing of the film. In a case of performing the post-baking, the post-baking temperature is preferably, for example, 100° C. to 240° C. From the viewpoint of curing of the film, the post-baking temperature is more preferably 200° C. to 230° C. The Young's modulus of the film after post-baking is preferably 0.5 to 20 GPa, and more preferably 2.5 to 15 GPa. In addition, in a case where a support on which the cured film is formed includes an organic electroluminescence (organic EL) element, an image sensor having a photo-electric conversion film constituted with organic materials, or the like, the post-baking temperature is preferably 150° C. or lower, more preferably 120° C. or lower, still more preferably 100° C. or lower, and particularly preferably 90° C. or lower. The lower limit can be set to, for example, 50° C. or higher. The post-baking can be performed continuously or batchwise by using a heating means such as a hot plate, a convection oven (hot-air circulating dryer), and a high-frequency heater so that the film after development (cured film) satisfies the conditions.

The cured film preferably has high flatness. Specifically, the surface roughness Ra is preferably 100 nm or less, more preferably 40 nm or less, and still more preferably 15 nm or less. The lower limit is not specified, but is preferably, for example 0.1 nm or more. The surface roughness can be measured, for example, using an atomic force microscope (AFM) Dimension 3100 manufactured by Veeco Instruments, Inc.

In addition, the contact angle of water on the cured film can be appropriately set to a preferred value, but is typically in the range of 50° to 110°. The contact angle can be measured, for example, using a contact angle meter CV-DT⋅A Model (manufactured by Kyowa Interface Science Co., Ltd.).

A higher volume resistivity value of each pattern (pixel) is desired. Specifically, the volume resistivity value of the pixel is preferably 10⁹ Ω·cm or more, and more preferably 10¹¹ Ω·cm or more. The upper limit is not defined, but is, for example, preferably 10¹⁴ Ω·cm or less. The volume resistivity value of the pixel can be measured, for example, using an ultra high resistance meter 5410 (manufactured by Advantest Corporation).

(Case of Forming Pattern by Dry Etching Method)

Pattern formation by a dry etching method can be performed by, for example, a method in which a coloring composition layer formed by applying a coloring composition onto a support or the like is cured to form a cured product layer, a patterned photoresist layer is then formed on the cured product layer, and the cured product layer is dry-etched with an etching gas, using the patterned photoresist layer as a mask.

As for the photoresist layer, it is preferable that a positive tone or negative tone radiation-sensitive composition is applied onto a cured product layer, and dried to form a photoresist layer. As the radiation-sensitive composition used for formation of the photoresist layer, a positive tone radiation-sensitive composition is preferably used. As the positive tone radiation-sensitive composition, a radiation-sensitive composition which is sensitive to radiations such as far ultraviolet-rays including ultraviolet rays (g-rays, h-rays, and i-rays), KrF-rays, ArF-rays, and the like, electron beams, ion beams, and X-rays is preferable. The above-mentioned positive tone radiation-sensitive composition is preferably a radiation-sensitive composition which is sensitive to KrF-rays, ArF-rays, i-rays, or X-rays, and from the viewpoint of micromachining, it is more preferably a radiation-sensitive composition which is sensitive to KrF-rays. As the positive tone photosensitive resin composition, the positive tone resist compositions described in JP2009-237173A or JP2010-134283A is suitably used. In the formation of a photoresist layer, an exposing step with the radiation-sensitive composition is preferably performed with KrF-rays, ArF-rays, i-rays, X-rays, or the like, more preferably performed with KrF-rays, ArF-rays, X-rays, or the like, and still more preferably performed with KrF-rays.

<Solid-State Imaging Element>

The solid-state imaging element of an embodiment of the present invention has the above-mentioned color filter of the embodiment of the present invention. The configuration of the solid-state imaging element of the embodiment of the present invention is not particularly limited as long as the solid-state imaging element is configured to include the color filter in the embodiment of the present invention and function as a solid-state imaging element. However, examples thereof include the following configurations.

The solid-state imaging element is configured to have a plurality of photodiodes constituting a light receiving area of the solid-state imaging element (a charge coupled device (CCD) image sensor, a complementary metal-oxide semiconductor (CMOS) image sensor, or the like), and a transfer electrode formed of polysilicon or the like on a substrate; have a light-shielding film having openings only over the light receiving portion of the photodiode, on the photodiodes and the transfer electrodes; have a device-protective film formed of silicon nitride or the like, which is formed to coat the entire surface of the light-shielding film and the light receiving portion of the photodiodes, on the light-shielding film; and have a color filter on the device-protective film. In addition, the solid-state imaging element may also be configured, for example, such that it has a light collecting means (for example, a microlens, which is the same hereinafter) on a device-protective film under a color filter (a side closer to the substrate), or has a light collecting means on a color filter. Further, the color filter may have a structure in which a cured film forming each colored pixel is embedded in, for example, a space partitioned in a lattice shape by a partition wall. The partition wall in this case preferably has a low refractive index for each colored pixel. Examples of an imaging device having such a structure include the devices described in JP2012-227478A and JP2014-179577A. An imaging device comprising the solid-state imaging element of the embodiment of the present invention can also be used as a vehicle camera or a monitoring camera, in addition to a digital camera or electronic equipment (mobile phones or the like) having an imaging function.

<Image Display Device>

The color filter of the embodiment of the present invention can be used for an image display device such as a liquid crystal display device and an organic electroluminescence display device. The definitions of image display devices or the details of the respective image display devices are described in, for example, “Electronic Display Device (Akio Sasaki, Kogyo Chosakai Publishing Co., Ltd., published in 1990)”, “Display Device (Sumiaki Ibuki, Sangyo Tosho Co., Ltd., published in 1989)”, and the like. In addition, the liquid crystal display device is described in, for example, “Liquid Crystal Display Technology for Next Generation (edited by Tatsuo Uchida, Kogyo Chosakai Publishing Co., Ltd., published in 1989)”. The liquid crystal display device to which the present invention can be applied is not particularly limited, and can be applied to, for example, liquid crystal display devices employing various systems described in the “Liquid Crystal Display Technology for Next Generation”.

### EXAMPLES

Hereinbelow, the present invention will be described in more detail with reference to Examples. The materials, the amounts of materials used, the proportions, the treatment details, the treatment procedure, or the like shown in the Examples below may be modified if appropriate as long as the modifications do not depart from the spirit of the present invention. Therefore, the scope of the present invention is not limited to the specific Examples shown below. In addition, “parts” and “%” are on a mass basis unless otherwise specified.

<Measurement of Weight-Average Molecular Weight>

The weight-average molecular weight of a resin was measured by the following method.

Types of columns: Columns formed by connection of TOSOH TSKgel Super HZM-H, TOSOH TSKgel Super HZ4000, and TOSOH TSKgel Super HZ2000

Developing solvent: Tetrahydrofuran Column temperature: 40° C.

Flow amount (amount of a sample to be injected): 1.0 μL (sample concentration: 0.1% by mass)

Device name: HLC-8220GPC manufactured by Tosoh Corporation Detector: Refractive index (RI) detector Calibration curve base resin: Polystyrene resin

<Preparation of Pigment Dispersion Composition>

A mixture with the composition shown below was uniformly stirred and mixed, and then mixed and dispersed for 3 hours with a beads mill to prepare each of pigment dispersion compositions.

(Red Pigment Dispersion Composition (R-1))

C. I. Pigment Red 254 . . . 7.0 parts by mass

C. I. Pigment Yellow 139 . . . 4.2 parts by mass

Disperbyk-111 (manufactured by BYK Chemie) . . . 1.1 parts by mass (non-volatile fraction)

The following resin A . . . 5.9 parts by mass (non-volatile fraction) Propylene glycol monomethyl ether acetate (PGMEA) . . . 81.5 parts by mass

(Red Pigment Dispersion Composition (R-2))

C. I. Pigment Red 177 . . . 7.0 parts by mass

C. I. Pigment Yellow 139 . . . 4.2 parts by mass

Disperbyk-111 (manufactured by BYK Chemie) . . . 1.1 parts by mass (non-volatile fraction)

The following resin A . . . 5.9 parts by mass (non-volatile fraction)

PGMEA . . . 81.5 parts by mass

(Red Pigment Dispersion Composition (R-3))

C. I. Pigment Red 264 . . . 7.0 parts by mass

C. I. Pigment Yellow 139 . . . 4.2 parts by mass

Disperbyk-111 (manufactured by BYK Chemie) . . . 1.1 parts by mass (non-volatile fraction)

The following resin A . . . 5.9 parts by mass (non-volatile fraction)

PGMEA . . . 81.5 parts by mass

(Red Pigment Dispersion Composition (R-4))

C. I. Pigment Red 254 . . . 7.0 parts by mass

C. I. Pigment Yellow 150 . . . 4.2 parts by mass

Disperbyk-111 (manufactured by BYK Chemie) . . . 1.1 parts by mass (non-volatile fraction)

The following resin A . . . 5.9 parts by mass (non-volatile fraction)

PGMEA . . . 81.5 parts by mass

(Red Pigment Dispersion Composition (R-5))

C. I. Pigment Red 254 . . . 7.0 parts by mass

C. I. Pigment Yellow 185 . . . 4.2 parts by mass

Disperbyk-111 (manufactured by BYK Chemie) . . . 1.1 parts by mass (non-volatile fraction)

The following resin A . . . 5.9 parts by mass (non-volatile fraction)

PGMEA . . . 81.5 parts by mass

(Orange Pigment Dispersion Composition (Or-1))

C. I. Pigment Orange 71 . . . 12.2 parts by mass

The following resin B . . . 5.0 parts by mass (non-volatile fraction)

PGMEA . . . 82.8 parts by mass

(Orange Pigment Dispersion Composition (Or-2))

C. I. Pigment Orange 38 . . . 12.2 parts by mass

The following resin B . . . 5.0 parts by mass (non-volatile fraction)

PGMEA . . . 82.8 parts by mass

(Yellow Pigment Dispersion Composition (Y-1))

C. I. Pigment Yellow 139 . . . 12.4 parts by mass

The following resin B . . . 3.80 parts by mass (non-volatile fraction)

PGMEA . . . 83.70 parts by mass

(Yellow Pigment Dispersion Composition (Y-2))

C. I. Pigment Yellow 150 . . . 12.4 parts by mass

The following resin B . . . 3.80 parts by mass (non-volatile fraction)

PGMEA . . . 83.70 parts by mass

(Yellow Pigment Dispersion Composition (Y-3))

C. I. Pigment Yellow 150 . . . 12.4 parts by mass

The following resin B . . . 3.80 parts by mass (non-volatile fraction)

PGMEA . . . 83.70 parts by mass

Resin A: A resin with the following structure (Mw=11,000, and the numerical values appended to the main chains are the numbers of moles)

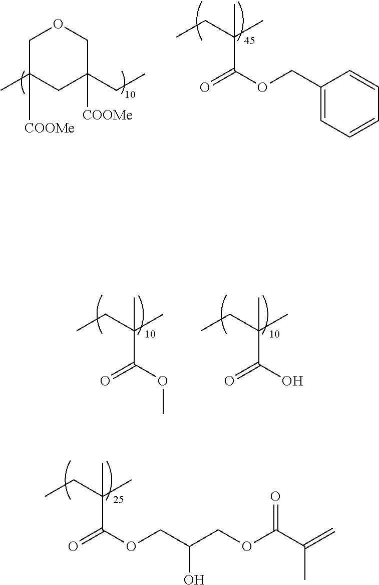

Resin B: A resin with the following structure (Mw=24,000, the numerical values appended to the main chains are the numbers of moles, and the numerical values appended to the side chains are the numbers of repeating units)

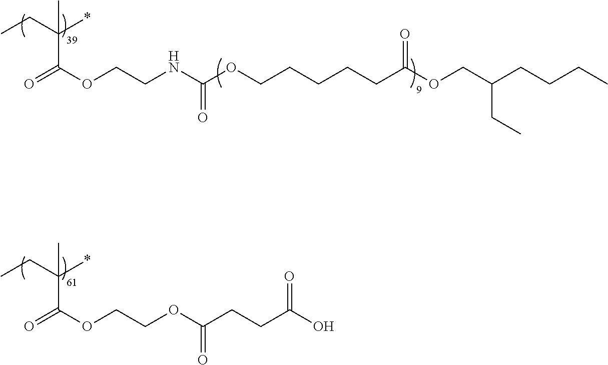

<Preparation of Coloring Composition>

The raw materials described in the following table were mixed to produce each of coloring compositions.

TABLE 1

| | Coloring composition | | | | | | | | | | | | |
|---|---|---|---|---|---|---|---|---|---|---|---|---|---|
| | RR-1 | RR-2 | RR-3 | RR-4 | RR-5 | RR-6 | RR-7 | RR-8 | RR-9 | RR-10 | RR-11 | RR-12 | RR-13 |
| Red pigment | 36.1 | 36.1 | 36.1 | | | 36.1 | | | 36.1 | 36.3 | 39.7 | 30.5 | 49.7 |
| dispersion | | | | | | | | | | | | | |
| composition (R-1) | | | | | | | | | | | | | |
| Red pigment | | | | 36.1 | | | | | | | | | |
| dispersion | | | | | | | | | | | | | |
| composition (R-2) | | | | | | | | | | | | | |
| Red pigment | | | | | 36.1 | | | | | | | | |
| dispersion | | | | | | | | | | | | | |
| composition (R-3) | | | | | | | | | | | | | |
| Red pigment | | | | | | | 36.1 | | | | | | |
| dispersion | | | | | | | | | | | | | |
| composition (R-4) | | | | | | | | | | | | | |
| Red pigment | | | | | | | | 36.1 | | | | | |
| dispersion | | | | | | | | | | | | | |
| composition (R-5) | | | | | | | | | | | | | |
| Orange pigment | 31.8 | 31.8 | 31.8 | 31.8 | 31.8 | | 31.8 | 31.8 | 31.8 | 42.7 | 19.7 | 31.9 | 31.9 |
| dispersion | | | | | | | | | | | | | |
| composition (Or-1) | | | | | | | | | | | | | |
| Orange pigment | | | | | | 31.8 | | | | | | | |
| dispersion | | | | | | | | | | | | | |
| composition (Or-2) | | | | | | | | | | | | | |
| Yellow pigment | 19.2 | 19.2 | 19.2 | 19.2 | 19.2 | 19.2 | | | 19.2 | 8.7 | 28.3 | 24.5 | 7.2 |
| dispersion | | | | | | | | | | | | | |
| composition (Y-1) | | | | | | | | | | | | | |
| Yellow pigment | | | | | | | 19.2 | | | | | | |
| dispersion | | | | | | | | | | | | | |
| composition (Y-2) | | | | | | | | | | | | | |
| Yellow pigment | | | | | | | | 19.2 | | | | | |
| dispersion | | | | | | | | | | | | | |
| composition (Y-3) | | | | | | | | | | | | | |
| Resin 1 | 1.7 | 1.7 | 1.7 | 1.7 | 1.7 | 1.7 | 1.7 | 1.7 | 1.7 | 1.3 | 1.7 | 2.2 | 0.4 |
| Photopolymerization | 0.9 | 0.9 | 0.9 | 0.9 | 0.9 | 0.9 | 0.9 | 0.9 | 0.9 | 0.9 | 0.9 | 0.9 | 0.9 |
| initiator 1 | | | | | | | | | | | | | |
| Ultraviolet absorber | 0.4 | 0.4 | 0.4 | 0.4 | 0.4 | 0.4 | 0.4 | 0.4 | 0.4 | 0.4 | 0.4 | 0.4 | 0.4 |
| 1 | | | | | | | | | | | | | |
| Curable compound 1 | 1.5 | | | 1.5 | 1.5 | 1.5 | 1.5 | 1.5 | 1.5 | 1.5 | 1.5 | 1.5 | 1.5 |
| Curable compound 2 | | 1.5 | | | | | | | | | | | |
| Curable compound 3 | | | 1.5 | | | | | | | | | | |
| Surfactant 1 | 4.2 | 4.2 | 4.2 | 4.2 | 4.2 | 4.2 | 4.2 | 4.2 | 4.2 | 4.2 | 4.2 | 4.2 | 4.2 |
| Solvent 1 | 4.2 | 4.2 | 4.2 | 4.2 | 4.2 | 4.2 | 4.2 | 4.2 | | 4 | 3.6 | 3.9 | 3.8 |
| Solvent 2 | | | | | | | | | 4.2 | | | | |

The raw materials described in the table are as follows.

Resin 1: A 40%-by-mass PGMEA solution of a resin with the following structure (Mw=24,000, the numerical values appended to the main chains are the numbers of moles, and the numerical values appended to the side chains are the numbers of repeating units)

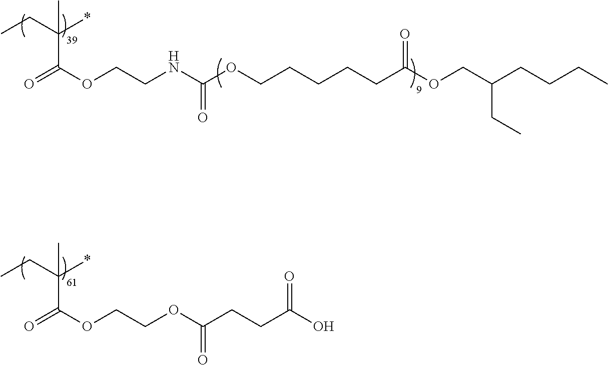

Photopolymerization initiator 1: IRGACURE OXE01 (manufactured by BASF)

Ultraviolet absorber 1: UV-503 (manufactured by Daito Chemical Co., Ltd.)

Curable compound 1: ARONIX M-350 (manufactured by Toagosei Chemical Co., Ltd., compound having ethylenically unsaturated bond groups)

Curable compound 2: NK Ester A-TMMT (manufactured by Shin-Nakamura Chemical Co., Ltd., compound having ethylenically unsaturated bond groups)

Curable compound 3: KAYARAD DPHA (manufactured by Nippon Kayaku Co., Ltd., compound having ethylenically unsaturated bond groups)

Surfactant 1: A 1%-by-mass PGMEA solution of the following mixture (Mw=14,000, and % representing a ratio of the repeating units in the following formula is % by mole)

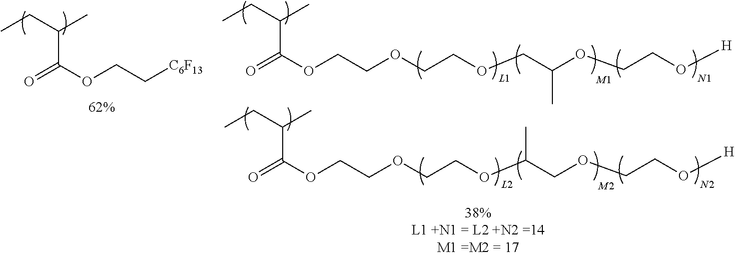

Solvent 1: PGMEA

Solvent 2: Cyclohexyl acetate

<Evaluation>

(Evaluation of Light Fastness)

Each of the coloring compositions was applied onto soda glass (75 mm×75 mm square, thickness of 1.1 mm) by a spin coating method at a rotation speed such that the film thickness after exposure became 1.0 μm. Then, the coloring composition on the soda glass was pre-baked at 100° C. for 2 minutes using a hot plate to obtain a coating film. The obtained coating film was exposed at an exposure dose of 1,000 mJ/cm² using an ultrahigh pressure mercury lamp (“USH-500BY” (trade name)) manufactured by Ushio Inc. Subsequently, the coating film after exposure was heated at 200° C. for 8 minutes using a hot plate in an air atmosphere to obtain a cured film. For the obtained cured film, a transmittance in a range of 400 nm to 700 nm was measured using “MCPD-3000” (trade name) manufactured by Otsuka Electronics Co., Ltd.

Next, the cured film was equipped with an ultraviolet ray-cut filter (KU-1000100 [trade name] manufactured by AS ONE Corporation), and irradiated with light at 100,000 lux for 100 hours (cumulative irradiation: 10,000,000 lux), using a light fastness tester (Xenon Weather Meter SX75 [trade name] manufactured by Suga Test Instruments Co., Ltd.) to perform a light fastness test. A temperature of the cured film (a temperature within the test device) was set to 63° C. A relative humidity within the test device was set to 50%. A variation in the transmittance of the cured film after the light fastness test was measured, and the light fastness was evaluated in accordance with the following standard. Further, a variation in the transmittance as compared indicates a variation with respect to a wavelength with the highest variation in the transmittance in the range of a wavelength of 400 nm to 700 nm (|Transmittance (%) before a light fastness test−Transmittance (%) after a light fastness test|).

3: A variation in the transmittance is 3% or less.

2: A variation in the transmittance is more than 3% and 5% or less.

1: A variation in the transmittance is more than 5%.

(Evaluation of Adhesiveness)

Each of the coloring compositions was applied onto an 8-inch (1 inch=2.54 cm) silicon wafer by a spin coating method, followed by pre-baking at 100° C. for 2 minutes using a hot plate to obtain a coating film. The obtained coating film was exposed (at an exposure dose of 50 to 1,700 mJ/cm²) through a mask with a pattern in 2.0 μm×2.0 μm, using an i-ray stepper exposure device “FPA-3000i5+” (trade name, manufactured by Canon Inc.). Then, the film after exposure was developed using a developing device (Act8 [trade name] manufactured by Tokyo Electron Ltd.). The film was subjected to shower development at 23° C. for 60 seconds using a 0.3%-by-mass aqueous tetramethylammonium hydroxide (TMAH) solution as a developer. Thereafter, the film was rinsed by spin shower using pure water to obtain a pattern.

The obtained pattern was observed using a scanning electron microscope (SEM) (S-4800H [trade name], manufactured by Hitachi High-Technologies Corporation) at a magnification of 20,000. Further, based on the observed image, the adhesiveness was evaluated in accordance with the following standard. A state where the pattern did not remain on an exposed area was counted as a pattern peeling.

3: The pattern peeling is less than 1%.

2: The pattern peeling is from 1% to 3%.

1: The pattern peeling is more than 3%.

The evaluation results of the light fastness and the adhesiveness are shown in the following table. Further, the mass ratio of the yellow pigment to the red pigment (yellow pigment/red pigment) and the mass ratio of the orange pigment to the red pigment (orange pigment/red pigment) in the coloring composition used are described in combination.

TABLE 2

| | Mass ratio of | Mass ratio of | | |
|---|---|---|---|---|
| | yellow pigment | orange pigment | | |
| Coloring | to red pigment | to red pigment | | |
| composition | (yellow pigment/ | (orange pigment/ | Light | Adhesive- |
| used | red pigment) | red pigment) | fastness | ness |
| RR-1 | 1.5 | 1.5 | 3 | 3 |
| RR-2 | 1.5 | 1.5 | 3 | 2 |
| RR-3 | 1.5 | 1.5 | 3 | 1 |
| RR-4 | 1.5 | 1.5 | 2 | 3 |
| RR-5 | 1.5 | 1.5 | 2 | 3 |
| RR-6 | 1.5 | 1.5 | 2 | 3 |
| RR-7 | 1.5 | 1.5 | 2 | 3 |
| RR-8 | 1.5 | 1.5 | 2 | 3 |
| RR-9 | 1.5 | 1.5 | 2 | 3 |
| RR-10 | 1 | 2 | 2 | 3 |
| RR-11 | 1.8 | 0.8 | 1 | 3 |
| RR-12 | 2 | 1.8 | 2 | 3 |
| RR-13 | 0.9 | 1.1 | 1 | 3 |

As shown in the table above, the cured films obtained using the coloring compositions RR-1 to 10 and RR-12 in which the mass ratio of the yellow pigment to the red pigment (yellow pigment/red pigment) was 1.0 to 2.0/1.0 and the mass ratio of the orange pigment to the red pigment (orange pigment/red pigment) was 0.9 to 2.0/1.0 had excellent light fastness and excellent adhesiveness.

What is claimed is:

1. A coloring composition comprising:
a pigment;
a resin; and
a curable compound,
wherein the pigment includes a red pigment, a yellow pigment, and an orange pigment, and
a mass ratio of the yellow pigment to the red pigment and a mass ratio of the orange pigment to the red pigment in the coloring composition are yellow pigment/red pigment=1.0 to 2.0/1.0 and orange pigment/red pigment=0.9 to 2.0/1.0, respectively.

2. The coloring composition according to claim 1,
wherein the red pigment is at least one selected from a diketopyrrolopyrrole compound, a quinacridone compound, an anthraquinone compound, a perylene compound, or an azo compound.

3. The coloring composition according to claim 1,
wherein the red pigment is Color Index Pigment Red 254.

4. The coloring composition according to claim 1,
wherein the orange pigment is at least one selected from a diketopyrrolopyrrole compound, an azo compound, a pyranthrone compound, a pyrazolone compound, or a phenanthroline compound.

5. The coloring composition according to claim 1,
wherein the orange pigment is Color Index Pigment Orange 71.

6. The coloring composition according to claim 1,
wherein the yellow pigment is at least one selected from an isoindoline compound, an azo compound, or a quinophthalone compound.

7. The coloring composition according to claim 1,
wherein the yellow pigment is Color Index Pigment Yellow 139.

8. The coloring composition according to claim 1,
wherein the red pigment is Color Index Pigment Red 254, the orange pigment is Color Index Pigment Orange 71, and the yellow pigment is Color Index Pigment Yellow 139.

9. The coloring composition according to claim 1,
wherein the curable compound contains a compound including 3 or more ethylenically unsaturated bond groups.

10. The coloring composition according to claim 9,
wherein the compound including 3 or more ethylenically unsaturated bond groups further has an alkyleneoxy group.

11. The coloring composition according to claim 1,
wherein the curable compound includes a compound having ethylenically unsaturated bond groups, and a content of a compound including 3 or more ethylenically unsaturated bond groups in the compound having ethylenically unsaturated bond groups is 60% by mass or more.

12. The coloring composition according to claim 1, further comprising an ultraviolet absorber.

13. The coloring composition according to claim 1, further comprising a photopolymerization initiator, an ultraviolet absorber and a surfactant.

14. A cured film obtained from the coloring composition according to claim 1.

15. A structure comprising an oxygen-shielding film formed on the cured film according to claim 14.

16. A color filter comprising the cured film according to claim 14.

17. A solid-state imaging element comprising the color filter according to claim 16.

18. An image display device comprising the color filter according to claim 16.
